(19) United States
(12) Patent Application Publication
(10) Pub. No.: US 2012/0174967 A1
(43) Pub. Date: Jul. 12, 2012

(54) PHOTOVOLTAIC MODULES AND MOUNTING SYSTEMS

(75) Inventors: David B. Pearce, Saratoga, CA (US); Dennis R. Hollars, San Jose, CA (US); Robert J. Cleereman, Midland, CA (US)

(73) Assignee: Nuvosun, Inc., Milpitas, CA (US)

(21) Appl. No.: 13/347,383

(22) Filed: Jan. 10, 2012

Related U.S. Application Data
(60) Provisional application No. 61/460,830, filed on Jan. 10, 2011.
(60) Provisional application No. 61/508,596, filed on Jul. 15, 2011.

(51) Int. Cl. H01L 31/048; H01L 31/02; H01L 31/0203

(52) U.S. Cl. 136/251; 136/259; 136/252

(57) ABSTRACT

A photovoltaic module includes a support member for securing a photovoltaic cell. The support member includes a plurality of holes extending through at least a portion of the support member. A mounting system includes a buss bar for coupling the photovoltaic module to a power transmission system.

### CROSS-REFERENCE

This application claims the benefit of U.S. Provisional Patent Application No. 61/460,830, filed on Jan. 10, 2011, and U.S. Provisional Patent Application No. 61/508,596, filed on Jul. 15, 2011, which applications are entirely incorporated herein by reference.

### BACKGROUND OF INVENTION

At least some current photovoltaic (PV) modules utilize crystalline silicon cells packaged with a low iron tempered glass top sheet, a TPE (Tedlar®, polyester, EVA) back sheet, an extruded aluminum frame, and a junction box with cables to connect to adjacent modules. While this module construction is the industry standard for silicon cells, the lowest cost module design for thin film solar cells is a frameless glass-glass package with a junction box or boxes and cables. This design was pioneered by First Solar for their CdTe thin film solar modules and has been adopted by some of the manufacturers of thin film copper indium gallium diselenide (CIGS) and amorphous silicon solar cells. The glass-glass structure provides the rigidity needed to eliminate the aluminum frame, while the soda lime glass back sheet is a lower cost component than a flexible back sheet containing Tedlar®. A significant disadvantage of the glass-glass frameless package is the added weight of the additional pane of glass. Therefore the cheaper glass-glass module is smaller than a framed glass-TPE module of equal weight. Smaller modules require more mounting hardware and additional installation labor for a complete system of a given size. Also, the geometry of a larger module provides a lower percentage aperture area loss from the non-active edge perimeter seal, and the cost of the junction box is amortized over more Watts of generated power.

Since silicon cells can be fragile and can withstand very little flexure before breaking, the modules generally are provided in frames with extruded aluminum channels to help provide the structural integrity that is needed to resist wind loading and other environmental and handling issues. Such frames, however, can be bulky, leading to increased manufacturing costs, both from a materials perspective and processing perspective, and the cost associated with transporting PV modules having the frames to a predetermined location.

### SUMMARY OF INVENTION

Recognized herein is the need for improved photovoltaic (PV) modules, including PV modules that are constructed to help reduce or minimize material and processing costs, in addition to costs associated with storing, transporting and installing PV modules.

Provided herein are PV modules that are lightweight in relation to current PV modules, and stiff. PV modules described in some embodiments aid in reducing or minimizing processing costs associated with PV module manufacturing, in addition to reducing or minimizing costs associated with storing, transporting and installing PV modules. PV modules provided herein can achieve the economies of glass-glass frameless modules in a larger lightweight module format.

In some embodiments, PV modules are provided with junction boxes, cable assemblies and buss bars that help lower materials and manufacturing costs, while also simplifying installation and reducing the cost associated with interconnecting modules to form PV arrays. In some situations, intricate junction boxes found in some current PV can be replaced with buss bars provided herein, which can allow a greater portion of the labor associated with PV module setup to be moved from the field to the factory.

An aspect of the invention provides a PV module, comprising a) a layer of an optically transparent material; b) a photovoltaic cell adjacent to the layer of the optically transparent material, the photovoltaic cell configured to generate electricity upon exposure to light; c) a dielectric layer adjacent to the photovoltaic cell; d) a metal foil adjacent to the dielectric layer, the metal foil for providing a moisture barrier; e) a support member adjacent to the metal foil; f) an edge seal between the layer of the optically transparent material and the metal foil; and g) an electrical connection member in electric communication with the photovoltaic cell, the electrical connection member for electrically coupling the photovoltaic cell to an electric buss bar. In an embodiment, the support member comprises through holes in a honeycomb configuration. In another embodiment, the electric connection member comprises power prongs for mating with a removable buss bar attachment member. In another embodiment, the photovoltaic cell is a thin film photovoltaic cell. In another embodiment, the photovoltaic cell comprises copper indium gallium diselenide. In another embodiment, the dielectric layer includes polyethylene terephthalate. In another embodiment, the metal foil includes aluminum. In another embodiment, the support member is formed of a polymeric material. In another embodiment, the polymeric material is polystyrene. In another embodiment, the support member is a polystyrene honeycomb structure that is molded from polystyrene. In another embodiment, the support member includes a thin back sheet with convective heat ventilation holes. In another embodiment, the electrical connection member is disposed adjacent to an edge of the support member. In another embodiment, the electrical connection member has a female configuration. In another embodiment, the electrical connection member has a male configuration. In another embodiment, the layer of the optically transparent material is formed of tempered glass. In another embodiment, the tempered glass has a low iron content. In another embodiment, the layer of the optically transparent material is formed of a transparent flexible moisture barrier sheet.

Another aspect of the invention provides a photovoltaic module, comprising a PV cell having an active material (or absorber) for generating electricity upon exposure of the PV cell to light; and a support member adjacent to the PV cell, the support member for providing structural support to the PV cell, the support member having a plurality of holes extending through the support member, an individual hole of the plurality of holes defined by a wall having at least one side. In an embodiment, the support member is formed of a polymeric material. In another embodiment, the plurality of holes are in a honeycomb configuration. In another embodiment, the active material includes CdTe, copper indium gallium diselenide, copper zinc tin sulfide, copper zinc tin selenium or amorphous silicon. In another embodiment, the support member comprises a support structure having the plurality of holes and a sheet adjacent to the support structure and disposed away from the PV cell, wherein each of the plurality of holes of the support structure has a width (W). In another embodiment, the sheet has holes aligned with the plurality of holes of the support structure, an individual hole of the plurality of holes of the sheet having a diameter (D), wherein D is less than W. In another embodiment, the wall has at least three sides. In another embodiment, the wall has at least four sides. In another embodiment, the wall has at least five sides. In another embodiment, the wall has at least six sides. In another embodiment, the support member includes a ridge encircling the PV cell, a light receiving surface of the PV cell below the ridge.

Another aspect of the invention provides a photovoltaic module, comprising a PV cell having an active material for generating electricity upon exposure of the PV cell to light; and a support member adjacent to the PV cell, the support member having a plurality of holes extending through at least a portion of the support member and along a direction generally orthogonal to a plane parallel to the PV cell. In some cases, a hole extends through at least 1%, 10%, 20%, 30%, 40%, 50%, 70%, 80%, 90%, 95%, or 99% of the support member.

Another aspect of the invention provides a photovoltaic module, comprising a PV cell having an active material for generating electricity upon exposure of the PV cell to light; and a support member adjacent to the PV cell, the support member having a plurality of holes extending through at least a portion of the support member. The PV module has a weight between about 10 kilograms (Kg) and 30 Kg, a length between about 1 meter (m) and 3 m, and a power output between about 100 watts (W) and 300 W. In an embodiment, the PV module has a weight between about 20 Kg and 22 Kg. In another embodiment, the PV module has a length between about 1.6 m and 2.2 m. In another embodiment, the PV module has a power output between about 160 W and 240 W. In another embodiment, the PV module has a width of about 1 m. In another embodiment, the plurality of holes are each defined by an enclosure having one or more walls, and wherein the support member has from about 40 to 160 enclosures per square foot. In another embodiment, the support member has from about 60 to 120 support cells per square foot. In another embodiment, the support member has from about 70 to 100 support cells per square foot.

Another aspect of the invention provides a lightweight PV module comprising a PV cell secured adjacent to a support member having one or more holes extending through at least a portion of the support member, the light weight PV module having a weight of between about 20 kilogram (Kg) and 22 Kg, a length of between about 1.6 meters (m) and 2.2 m, and a power output of between about 160 W and 240 W. In an embodiment, an individual hole of the one or more holes is defined by an enclosure of a support cell of the support member, wherein the support member has from about 40 to 160 support cells per square foot.

Another aspect of the invention provides a PV module, comprising a PV cell secured adjacent to a support member, the support member having a plurality of support cells, each support cell of the plurality of support cells having an enclosure defining a hole that extends through at least a portion of the support member, the support member having between about 40 and 160 support cells per square foot. In an embodiment, the hole extends through substantially all of the support member. The hole can extend along a direction orthogonal to opposing top and bottom surfaces of the support member, the top surface adjacent to the PV cell. In another embodiment, the support member has between about 60 and 120 support cells per square foot. In another embodiment, the support member has between about 70 and 100 support cells per square foot. In another embodiment, the hole extends through substantially the whole support member. In another embodiment, the PV module has a weight of between about 10 Kg and 30 Kg. In another embodiment, the PV module has a weight of between about 20 Kg and 22 Kg. In another embodiment, the PV module has a length of between about 1 m and 3 m. In another embodiment, the PV module has a length of between about 1.6 m and 2.2 m. In another embodiment, the PV module has a power output of between about 100 W and 300 W. In another embodiment, the PV module has a power output of between about 160 W and 240 W.

Another aspect of the invention provides a stack of photovoltaic modules, comprising a plurality of PV modules, an individual PV module of the plurality of PV modules as described above, alone or in combination. Adjacent PV modules of the plurality of PV modules are secured against one another with the aid of ridges formed in support members of the PV modules, the ridges encircling PV cells of the PV modules. A ridge can be unitary (or single-piece) with a support member of an individual PV module.

Another aspect of the invention provides a PV mounting system, comprising: a) an open bottom mounting channel; b) a closed top mounting channel with at least one electrical plug connection; c) a securing member to secure a PV module; and d) a supporting structures for the mounting channels.

Another aspect of the invention provides a photovoltaic array, comprising a mounting frame; a buss bar secured against the mounting frame, the buss bar for providing power distribution; and a plurality of PV modules secured against the mounting frame and electrically coupled to the buss bar, an individual PV module of the plurality of PV modules having a support member for providing structural support to a PV cell of the individual PV module, the support member having a plurality of holes extending through the support member. In an embodiment, the mounting frame comprises a first and second support member and a third support member disposed between the first and second support members, wherein the buss bar is secured against the third support member. In another embodiment, the first, second and third support members have circular cross-sections. In another embodiment, the individual PV module is electrically coupled to the buss bar in a plug-and-play configuration. In another embodiment, the plurality of PV modules are each electrically coupled to the buss bar with the aid of an electrical attachment member coupled to an electrical receptacle of the buss bar.

Another aspect of the invention provides a method for transporting a photovoltaic module, comprising stacking a plurality of PV modules to form a PV module stack, each PV module of the PV module stack as described above, alone or in combination, and transporting the PV module stack to a target location. The PV module stack can be transported with the aid of a transportation vehicle, such as an automobile, truck, airplane or boat.

Another aspect of the invention provides a method for installing a PV module, comprising securing a PV module as described above, alone or in combination, against a mounting frame.

Another aspect of the invention provides a method for manufacturing a photovoltaic module, comprising securing a PV cell to a support member, the support member for providing structural support to the PV cell, the support member having a plurality of holes extending through the support member, an individual hole of the plurality of holes defined by a wall having at least one side. In an embodiment, the plurality of holes are in a honeycomb configuration. In another embodiment, the PV cell comprises an active material having CdTe, copper indium gallium diselenide, copper zinc tin sulfide, copper zinc tin selenium or amorphous silicon. In another embodiment, the support member comprises a support structure having the plurality of holes and a sheet adjacent to the support structure and disposed away from the PV cell, wherein each of the plurality of holes of the support structure has a width (W). In another embodiment, the sheet has a plurality of holes, wherein an individual hole of the plurality of holes of the sheet is aligned with an individual hole of the plurality of holes of the support structure, wherein an individual hole of the plurality of holes of the sheet has a diameter (D), and wherein D is less than the width (W). In another embodiment, the wall has at least three sides. In another embodiment, the wall has at least four sides. In another embodiment, the wall has at least five sides. In another embodiment, the wall has at least six sides.

Another aspect of the invention provides a light weight integrated roof mounting system that eliminates the conventional mounting structure and roof penetrating hardware.

Another aspect of the invention provides a plug-and-play or snap-in PV module configured for installation with reduced labor and expenses in relation to current PV modules. In some situations, PV modules are formed without junction boxes, but are electrically coupled to a power distribution system with the aid of buss bars provided herein.

Another aspect of the invention provides stackable PV modules. PV modules can include support members to enable the PV modules to be stacked without the need for additional filler or support material between the PV modules.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure. Accordingly, the drawings and description are to be regarded as illustrative in nature, and not as restrictive.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings or figures (also “FIG.” or “FIGS.” herein) of which:

FIG. 1 schematically illustrates a photovoltaic (PV) module, in accordance with an embodiment of the invention;

FIG. 2 is a schematic top view of a PV module having a hexagonal support member, in accordance with an embodiment of the invention;

FIG. 3 schematically illustrates a support member, in accordance with an embodiment of the invention;

FIGS. 4-6 schematically illustrate enlarged portions of the support member of FIG. 3;

FIG. 7 schematically illustrates an electrical attachment member, in accordance with an embodiment of the invention;

FIG. 8 schematically illustrates a mounting frame, in accordance with an embodiment of the invention;

FIG. 9 schematically illustrates a PV array having PV modules mounted on the mounting frame of FIG. 8, in accordance with an embodiment of the invention;

FIG. 10 is an enlarged view of a portion of the mounting frame of FIG. 9, in accordance with an embodiment of the invention;

FIG. 11 schematically illustrates a buss bar for use with the PV array of FIGS. 9 and 10, in accordance with an embodiment of the invention;

FIG. 12 schematically illustrates an underside of select PV modules of FIGS. 9-11, in accordance with an embodiment of the invention;

FIGS. 13A and 13B schematically illustrate a mounting and electrical attachment system, in accordance with an embodiment of the invention;

FIG. 14 schematically illustrate a plurality of buss bars mounted on a horizontal support member, in accordance with an embodiment of the invention. The bottom image is an enlarged view of the boxed portion of the top image;

FIG. 15 schematically illustrates a electrical attachment member, in accordance with an embodiment of the invention;

FIG. 16 schematically illustrates a linker, in accordance with an embodiment of the invention;

FIG. 17 shows a PV array having a PV module, in accordance with an embodiment of the invention;

FIGS. 18A-18C schematically illustrate a support member and attachment member of the PV array of FIG. 17, in accordance with an embodiment of the invention;

FIGS. 19A-19D schematically illustrate the attachment member of FIGS. 18A-18C, in accordance with an embodiment of the invention;

FIG. 20 schematically illustrates a mounting frame for a PV module, in accordance with an embodiment of the invention;

FIG. 21 is schematic cross-sectional side view of a mounting system for a single row of PV modules, in accordance with an embodiment of the invention;

FIG. 22 is a schematic side view of a region of closed top channel of the mounting system of FIG. 21, in accordance with an embodiment of the invention;

FIG. 23 is an expanded cross sectional view of a top mounting channel and module plug connection, in accordance with an embodiment of the invention;

FIG. 24 is a schematic side view of a double module mounting system, in accordance with an embodiment of the invention;

FIG. 25 is a schematic cross-sectional side view of a mounting channel and module plug connections, in accordance with an embodiment of the invention;

FIG. 26 schematically illustrates a PV module for residential rooftop mounting, in accordance with an embodiment of the invention;

FIG. 27 is a schematic side view of PV module mounted on a rooftop, in accordance with an embodiment of the invention; and

FIG. 28 is a schematic side view of a PV module mounted on a roof structure, in accordance with an embodiment of the invention.

### DETAILED DESCRIPTION OF INVENTION

While various embodiments of the invention have been shown and described herein, it will be obvious to those skilled in the art that such embodiments are provided by way of example only. Numerous variations, changes, and substitutions may occur to those skilled in the art without departing from the invention. It should be understood that various alternatives to the embodiments of the invention described herein may be employed in practicing the invention.

The term “photovoltaic cell” or “solar cell,” as used herein, refers to a solid state electrical device having an active material (or absorber) that converts the energy of light into electricity by the photovoltaic (PV) effect.

The term “photovoltaic module” or “solar module,” as used herein, refers to a packaged array of one or more PV cells. The PV module (also “module” herein) can be used as a component of a larger photovoltaic system to generate and supply electricity, such as in commercial and residential applications. A PV module can include a support structure having one or more PV cells. In some embodiments, a PV module includes a plurality of PV cells, which can be interconnected, such as, for example, in series with the aid of interconnects. A PV array can include a plurality of PV modules.

Some embodiments provide photovoltaic modules that include support members that are lightweight. This can be achieved by reducing, if not minimizing, the material used to construct the support members. Such lightweight construction can aid in reducing, if not minimizing, the cost to transport the PV modules from a point of manufacture or storage to a point of installation. Some embodiments provide PV modules that can be readily stacked without the need for additional filler material between the PV modules to prevent damage to PV cells, such as foam fillers, as may be used to transport at least some current PV modules. In some cases, this is achieved with the aid of ridges on a support member of a PV module, which enables a top portion of a PV module to be secured against a bottom portion of an overlying PV module during transport. This can enable at least 2, 3, 4, 5, 6, 7, 8, 9, 10, 20, 30, 40, 50, 60, 70, 80, 90, 100, 500, 1000, or more PV modules to be transported at the same time. Such features, individually or collectively, can aid in reducing, if not minimizing, the cost associated with transporting PV modules, in addition to reducing pollution and even offsetting the effects of global warming, as the amount of fuel used to transport the PV modules is reduced in relation to amount of fuel used to transport current PV modules.

In some situations, PV modules are configured to be stacked on top of one another without the need for additional filler or support material, which can further aid in reducing transportation costs. This may enable PV modules to be packaged in stacks and stored or shipped to a target location, including a location for sale, storage, installation or distribution, such as, for example, a plot of land, a rooftop, a vehicle or a warehouse.

Some embodiments provide PV modules configured for assembly in arrays having a plurality of modules. The PV modules include electrical buss bars to enable the PV modules to be electrically coupled to a power distribution system, and attachment members to enable the PV modules to be mounted to a support structure installed on predetermined area, such as a rooftop.

Photovoltaic modules provided herein can include thin film PV (solar) cells. Thin film solar cells can be formed on flexible substrates and can be employed in a wider range of module designs than those with silicon cells. Thin film modules can come in a variety of formats, depending, for example, on the thin film deposition process (e.g., chemical vapor deposition, atomic layer deposition, molecular beam epitaxy, sputtering) used to form the thin film modules. Thin film solar cells can include an active material (or “absorber”) having CdTe, copper indium gallium diselenide (CIGS), copper zinc tin sulfide (CZTS), copper zinc tin selenium (CZTSe), or amorphous silicon PV active materials, the active material configured to generate electricity upon exposure to light (hv).

In some embodiments, a thin films PV cell deposited on a glass substrate can be monolithically integrated with a second top sheet of glass laminated over the thin film structure with a thermoplastic adhesive or other fastening member, such as a mechanical fastener. In particular, CIGS thin film cells deposited on glass substrates use the glass-glass format. However, thin film solar cells deposited on thin flexible substrates, like metal foils, can be made by lower cost roll-to-roll processes, and they can use back sheets other than glass. For example, the thermoplastic elastomer (TPE) back sheet for silicon cells can be produced as a TAPE back sheet for thin film modules, where the “A” stands for the addition of a thin sheet of aluminum foil that can serve as a moisture barrier for moisture sensitive thin film PV (or solar) cells.

### Photovoltaic Modules

An aspect of the invention provides a photovoltaic (PV) module, comprising a layer of an optically transparent material, a photovoltaic (PV) cell adjacent to the layer of the optically transparent material, a dielectric layer adjacent to the photovoltaic cell, a metal foil adjacent to the dielectric layer, the metal foil for providing a moisture barrier, a support member adjacent to the metal foil, and an electrical connection member in electric communication with the photovoltaic cell, the electrical connection member for electrically coupling the photovoltaic cell to an electric buss bar. The PV module in some cases includes an edge seal between the layer of the optically transparent material and the metal foil. The layer of the optically transparent material can be transparent or partially transparent (semi-transparent) to solar radiation (hv).

The PV cell can be a thin film PV cell, formed with the aid of various thin film deposition processes, such as atomic layer deposition (ALD), chemical vapor deposition (CVD), molecular beam epitaxy (MBE), physical vapor deposition (e.g., sputtering), or plasma-enhanced vapor deposition, such as plasma-enhanced ALD or plasma-enhanced CVD. A PV cell in some cases can have a thin film formed of CdTe, CIGS, CZTS, CZTSe or amorphous silicon. A thin film solar cell can have an active layer (or absorber) thickness between about 50 nanometers (nm) and 5 micrometers (microns), or 100 nm and 2 microns, or 500 nm and 1 micron.

In an embodiment, a PV module includes a PV cell adjacent to a support member having a support structure with a plurality of holes. The plurality of holes can be distributed in a predetermined fashion to form a pattern of holes, such as, for example, a pattern of holes in a honeycomb configuration. In some cases, an individual hole of the plurality of holes is defined by an enclosure. The enclosure can have 1, 2, 3, 4, 5, 6, 7, 8, 9, 10, or more walls. In an exemplary implementation, the enclosure has six walls, in which case the enclosure is hexagonal. Such a support structure enables the support member to provide the minimum structural integrity needed to resist wind loading and other environmental and handling issues, while aiding in minimizing material expenses and weight. A reduction in weight can help reduce, if not minimize, the cost associated with manufacturing, transporting, installing and/or maintaining PV modules, thus aiding in reducing pollution and offsetting the effects of global warming.

In some situations, an individual hole of the plurality of holes extends at least partially through the support structure. In other situations, the individual hole extends completely through the support structure.

In some embodiments, a PV module provided herein have a weight of about 10 kilograms (Kg) to 30 Kg, or 20 Kg to 22 Kg, for a PV module having a width of about 0.5 meter (m) to 3 m, or 0.7 m to 1.5. m, or about 1 m, and a length of about 1 m to 3 m, or 1.6 m to 2.2 m. In some embodiments, PV modules provided herein have a power output of about 100 watts (W) to 300 W, or 160 W to 240 W.

Some embodiments, provide a photovoltaic module comprising a PV cell having an active material for generating electricity upon exposure of the PV cell to light, and a support member adjacent to the PV cell. The support member has a plurality of holes extending through at least a portion of the support member and along a direction generally orthogonal to a plane parallel to the PV cell. In some cases, a hole extends through at least 1%, 10%, 20%, 30%, 40%, 50%, 70%, 80%, 90%, 95%, or 99% of the support member.

Reference will now be made to the figures, wherein like numerals refer to like parts throughout. It will be appreciated that the figures and structures therein are not necessarily drawn to scale.

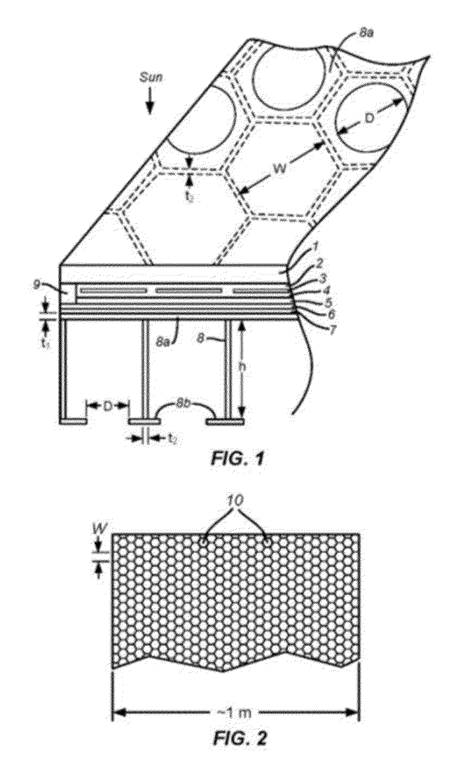

FIG. 1 schematically illustrates a photovoltaic (PV) module, in accordance with an embodiment of the invention. The module of FIG. 1 includes a layer of an optically transparent material 1, such as low iron tempered glass. The layer of the optically transparent material 1 is configured to permit light (hv) to enter the module. In an example, the layer of the optically transparent material 1 includes tempered glass having a thickness between about 1 mm and 5 mm, or 2 mm and 4 mm. The tempered glass in some cases is low iron tempered glass. In an example, the layer of the optically transparent material 1 has a thickness of about 3.2 mm. The module further includes an adhesive 2 and a photovoltaic (PV) cell layer 3. The PV cell layer 3 includes a plurality of PV cells, each of which can include CdTe, CIGS, CZTS, CZTSe or amorphous silicon PV active materials (or absorbers). In some cases, however, the PV cell layer 3 can include a single PV cell. The adhesive layer 2 is used to affix the PV cell 3 to the layer of the optically transparent material 1. The adhesive layer 2 can include ethylene vinyl acetate (EVA). The module further includes an adhesive layer 4, which can be formed of the same material as the adhesive layer 2. The adhesive layer 4 secures said PV cell 3 to a dielectric layer 5, which is disposed adjacent to a moisture barrier metal foil 6. The dielectric layer 5 can be formed of polyethylene terephthalate (PET) and metal foil layer 6 can be formed of aluminum, in some cases with a composition similar to TAPE. Alternatively, a thin dielectric film with moisture barrier properties deposited on a thin substrate can be used in place of the dielectric layer 5 and the metal foil layer 6.

With continued reference to FIG. 1, the module includes a support member disposed adjacent to a stack having the layers 1-6. In some cases, the support member has a plurality of through holes in a honeycomb configuration. Each individual hole is hexagonal in shape—that is, an individual hole is defined by an enclosure having six sides. The support member can be formed of a polymeric material, carbon fiber material, or composite material.

In the illustrated embodiment of FIG. 1, an adhesive layer 7 bonds an inner sheet 8a to the layers 1-6, and a hexagonal (honeycomb) support structure 8 is bonded to inner sheet 8a by way of a diffusion weld. Such a configuration can replace the relatively expensive “T” (Tedlar®) in the commonly used TAPE stack. In some cases, the support member 8 can be bonded to the inner sheet 8a with the aid of an adhesive or one or more mechanical fasteners, such as a screws, stables, or clamps.

In an embodiment, the inner sheet 8a is an inner sheet with thickness t1 and support structure 8 has webs of thickness t2, height h, and characteristic cell width (W). The support structure 8 and inner sheet 8a can be formed of a polymeric material, such as with the aid of injection molding methods. In an example, the support structure 8 and inner sheet 8a are formed by an injection molded part made from an economical polymer material, for instance polystyrene, polyethylene, polypropylene, polyvinyl chloride (PVC) or a material resistive to ultraviolet (UV) radiation. This can eliminate the need to join 8a and 8 with the aid of a weld.

The support structure 8 comprises through holes in various shapes and configurations, such as packing density. In an example, the through holes are in a honeycomb configuration, with each individual hole having six walls. The holes can have other geometrical shapes, such as, for instance, circles, triangles, squares, rectangles, pentagons, heptagons, or octagons. The through holes may be packed in a hexagonal close packing (hcp) configuration, though other packing arrangements, such as face centered cubic (fcc), may be used.

The parameters ‘t1’, ‘t2’, ‘h’, and ‘W’ can be adjusted depending upon the strength of the polymer material to give approximately the same stiffness as the sheet of glass it replaces. The stiffness can also be made to duplicate the stiffness of a conventional aluminum framed module, which may not be different from the case for glass. Web thickness ‘t2’ need not be the same as inner sheet thickness ‘t1’, although they may be. These thicknesses, ‘t1’ and ‘t2’, can be between about 0.01 inches and 1 inch, or 0.02 inches and 0.1 inches. Cell width ‘W’ can be between about 0.1 inches and 2 inches, or 0.5 inches and 1.5 inches, and web height ‘h’ can be between about 0.1 inches and 2 inches, or 0.5 inches and 1.5 inches. In some cases, the stiffness can be proportional to the cube of the thickness for a plate of material, and the useful thicknesses tend to fall in a fairly narrow range. To gain additional stiffness without adding substantial weight, an additional sheet 8b with thickness similar to ‘t1’ and ‘t2’ may be bonded to the back. This outer sheet can have openings (i.e., round holes) centered on the hex pattern with diameter ‘D’ to allow for convective heat loss from the module during solar exposure. The sheet 8b can be formed of a polymeric material or a metallic material, such as aluminum.

In the manufacturing of the module, sheets of the various materials are stacked together along with an edge seal 9, and the materials are bonded together at an elevated temperature, in some cases under vacuum or in an inert environment (e.g., N₂, Ar or He). In some cases, the PV cell 3 is laterally bounded by the edge seal 9. The edge seal 9 can be a standalone component that is secured against the layers 2-5. Alternatively, the edge seal 9 can be formed as part of the inner sheet 8a or the support structure 8.

The support structure 8 can be formed in a mold, and the thickness parameters may also be varied locally a mold, template or panel used to form the support structure 8. For instance, any of the dimensions of support structure 8, even including web height ‘h’, can be changed to accomplish local strengthening at some positions. In some cases, the ‘h’ can be changed in the areas of module mounting where higher stresses may be encountered. These areas can be made more robust while low stress areas may be thinned, thus maximizing the overall stiffness for a given weight of material while adding strength at selected areas. In some cases, the thickness, ‘t1’ of inner sheet 8a contributes little to the stiffness of the support structure 8, since the loads are ultimately transferred to the glass by a sufficiently strong bond. In such cases, a thin inner sheet 8a can aid in achieving a reliable bond. The inner sheet 8a can be thinned to reduce weight. In some embodiments, the inner sheet 8a can be precluded if adequate bonding can be made between the cell walls of the support structure 8 and layer 6.

The support structure 8 and, if used, one or both of the inner sheet 8a and outer sheet 8b can define a support member of the PV module of FIG. 1. In some embodiments, one or both of the inner sheet 8a and outer sheet 8b are integral with the support structure 8. In some cases, the inner sheet 8a, support structure 8 and outer sheet 8b are formed as a single part. In other cases, the inner sheet 8a and support structure 8 are formed as a single part and the outer sheet 8b is secured against the support structure 8, such as with the aid of welding. In other cases, the support structure 8 and outer sheet 8b are formed as a single part, and the inner sheet 8a is secured against the support structure 8, such as with the aid of welding. This can be used in a case where the edges of the support structure 8 do not bond to layer 6 as well as they may bind to a similar structure or material as that of inner sheet 8a. The bond between the support structure 8 and layer 6 can be spread over the whole area of the module for better overall strength.

In some cases, the support member includes holes extending through at least a portion of the support structure 8, in some cases extending through the entire support member. A hole can be defined by an enclosure, such as an enclosure having six walls in a hexagonal configuration. The enclosure is included in the support structure 8. An enclosure with a hole extending through at least a portion of the support structure 8 can be referred to as a “support cell.” The support cell is in fluid communication with a hole, such as a hole in the sheet 8b, that can provide fluid flow (e.g., air flow) for convective cooling of the PV cell 3. The strength of the support member, including the support structure 8, can be a function of the geometry of the support cell, including the size of the support cell. In some cases, a support member has from about 40 to 160 support cells per square foot, or 60 to 120 support cells per square foot, or 70 to 100 support cells per square foot. The square footage can be in relation to a cross-sectional area of the support member. In an example, a support member has 80 support cells per square foot. In some cases, the support cells are distributed in a side-by-side fashion. In some embodiments, the support cells are in a close packing arrangement, such as hexagonal close packing (hcp) or face centered cubic (fcc) arrangement. Each individual support cell can have a height that is less than or equal to the height (h) of the support structure 8.

The number density of support cells can inversely scale with the thickness of a wall of the support cell or the height (h) of the support structure 8. In an example, decreasing the support cell density can require an increase in the height of the support structure 8 or an increase in the thickness of one or more walls defining an enclosure of a support cell. In some cases, for a support structure formed of a polymeric material, the thickness is from about 1 inch to 3 inches, or 1.5 inches to 2.0 inches.

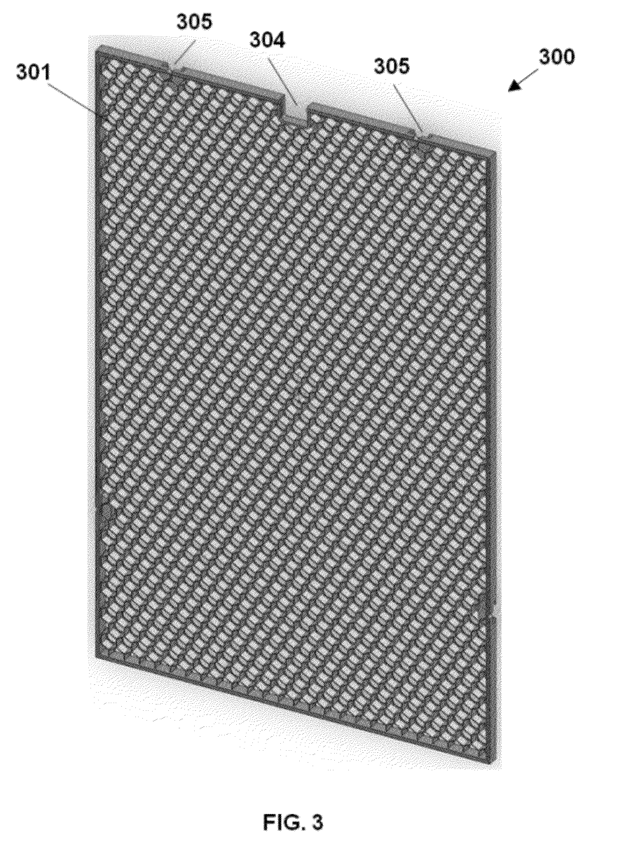

FIG. 2 is a schematic back view of a top section of a PV module. The PV module has a characteristic cell width (W). The PV module of FIG. 2 can be illustrative of a PV module of FIG. 1 with a hexagonal support member. For a width of about 1.25 inches the PV module of FIG. 2 can have a module width of about one meter as indicated. This can provide a PV module, including support member, with structural integrity that is needed to resist wind loading and other environmental and handling issues. In some cases, doubling the width can increase the height (h) by a factor of about 2̂(1/3) (or about 1.26). For a module length of 1 meter by 1.6 meters, the overall module size can be about the same as that of conventional frame constructed silicon modules, but with lower cost and in some cases lower weight. The weight of the PV module can be less than a glass-glass design of equal size.

With continued reference to FIG. 2, the PV module includes one or more female plug receptacles 10 near the top of the module to provide electrical connections to the cells in the module. The plugs are shown as fitting within the cell dimension of the hexagonal structure, although other plug configurations are possible. The plugs can span a region where the web is removed (or not molded initially) and they need not be round in shape. The plugs 10 in some cases can have a male configuration.

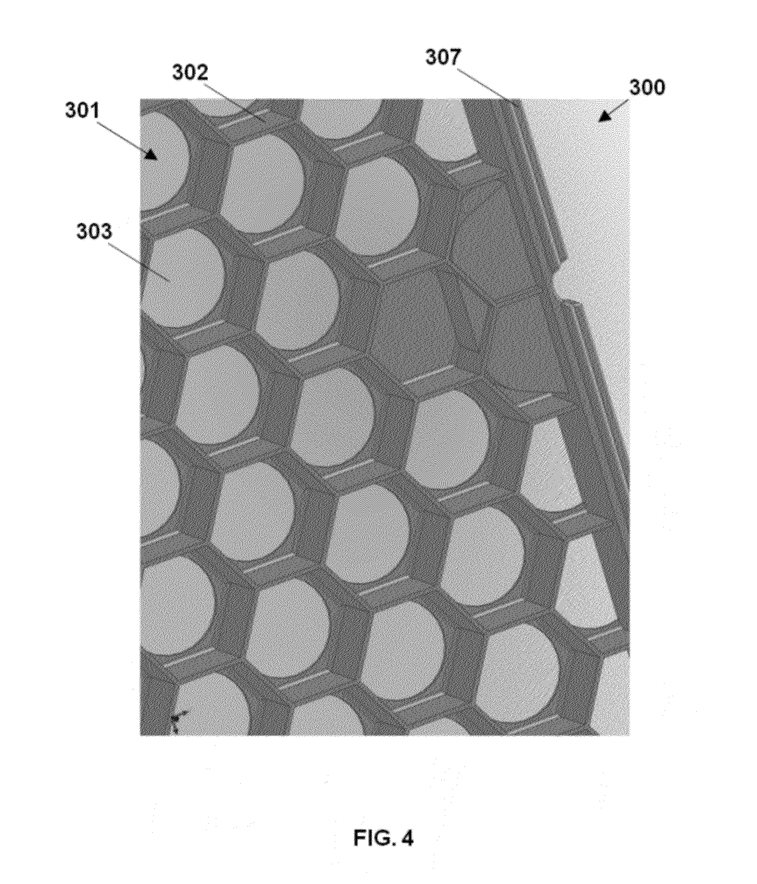

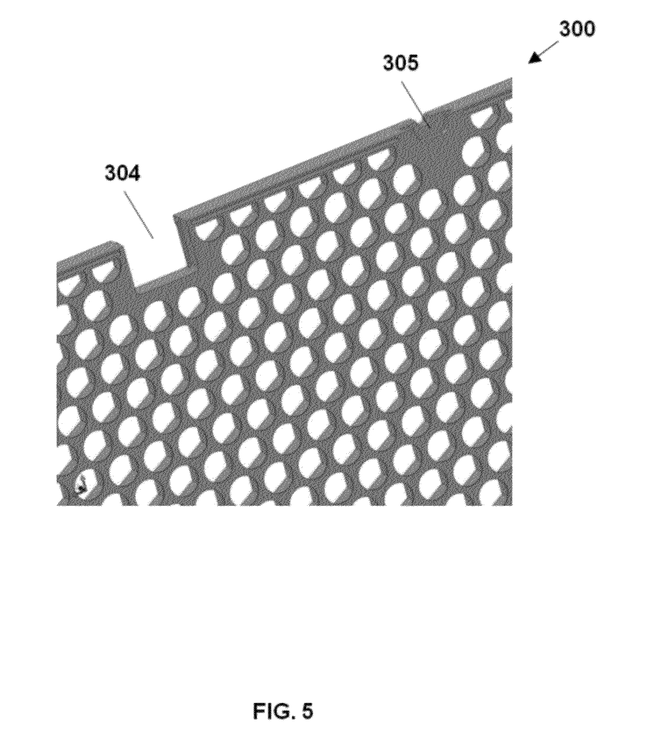

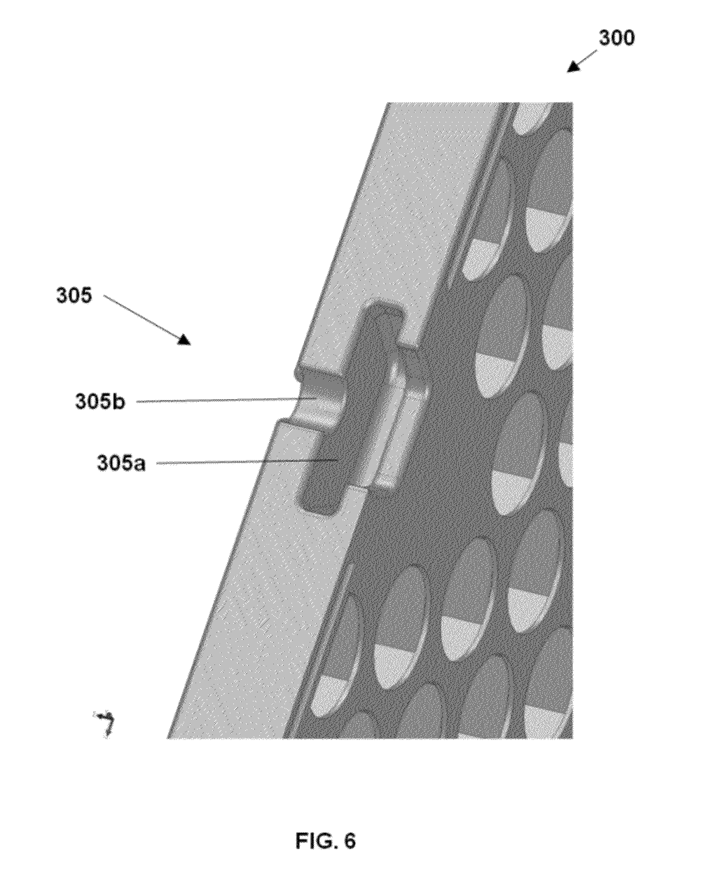

FIG. 3 schematically illustrates a support member 300 for supporting one or more PV cells (not shown), in accordance with an embodiment of the invention. FIGS. 4-6 are enlarged views of portions of the support member 300 of FIG. 3. The support member 300 includes holes 301. The holes 301 can be referred to as through holes in some cases. An individual hole 301 is defined by an enclosure having six sidewalls 302. The holes are thus hexagonal. In some cases, an individual hole 301 is bounded by six other holes. Such a configuration can aid in maximizing the packing density of holes in the support member 300.

Some embodiments provide holes defined by enclosures having have 1, 2, 3, 4, 5, 6, 7, 8, 9, 10, or more sidewalls. In some cases, holes have circular, triangular, square, rectangular, pentagonal, hexagonal, heptagonal, octagonal, or nonagonal cross-sections. An enclosure with a hole extending through at least a portion of the support member 300 can be collectively referred to as a “support cell.” The support member 300 includes a plurality of support cells.

The support member 300 can include a sheet 303, which can be unitary with the support member or separately formed and fastened to the support member, such as with the aid of an adhesive. The sheet 303 is disposed behind a hole 301 in the context of the figure. The sheet 303 can be similar to the sheet 8b discussed above in the context of FIG. 1. The sheet 303 includes holes that are aligned with the holes 301.

A PV module can be constructed by resting one or more PV cells (not shown) adjacent to the support member 300 and fastening the one or more PV cells to the support member 300, as described above in the context of FIGS. 1 and 2. If a plurality of PV cells are used, the PV cells can be interconnected in series. The PV module can then be mounted to a mounting frame, as described below. Various structural features of the support member 300 enable the PV module to be mounted to the mounting frame and electrical coupled to a power distribution system, which can include an energy storage system.

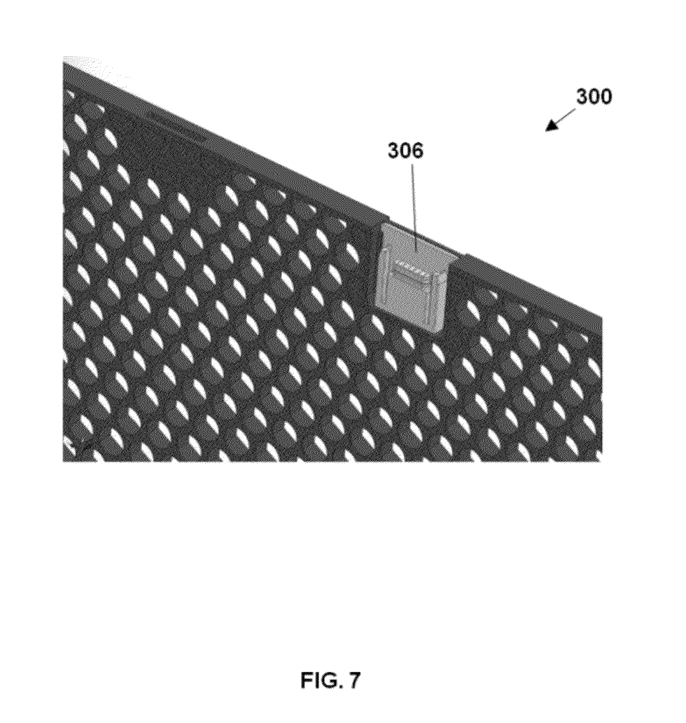

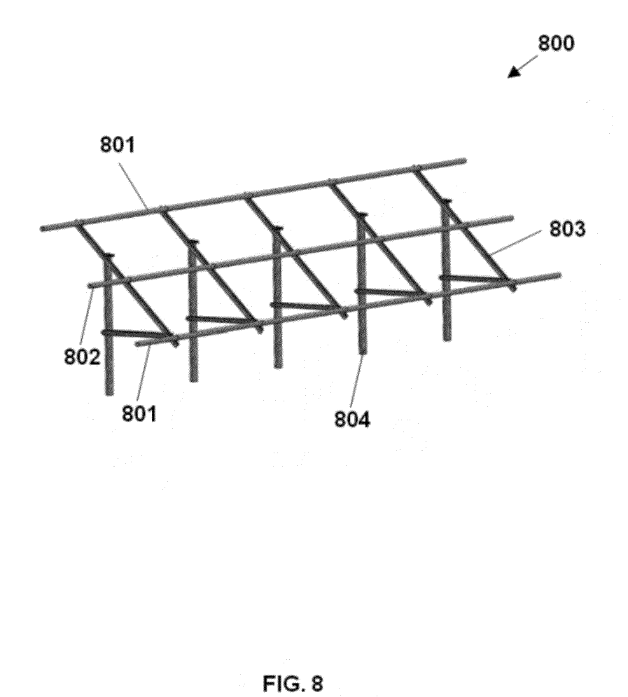

With reference to FIG. 3, the support member 300 includes a slot 304 for accepting an electrical attachment member for coupling a PV module, as formed from the support member 300, to an electrical buss bar of a mounting frame. FIG. 7 shows an electrical attachment member 306 mounted in the slot 304. The electrical attachment member 306 can be removable from the slot 304, or irremovably attached to the support member 300, such as with the aid of an epoxy or mechanical fastener (e.g. screws). In some cases, the electrical attachment member 306 is unitary (or singe-piece) with the support member 300 (see below). The electrical attachment member 306 is configured to mount to a receptacle of the buss bar as part of the power distribution system. The support member 300 further includes slots 305 for providing attachment members for mounting the support member 300 to a mounting frame. FIG. 6 shows an enlarged view of the slot 305. The slot 305 includes a cavity 305a and port 305b for enabling the attachment member (not shown) to secure the support member 300 to a mounting frame.

The support member 300 can be formed of a polymeric material, such as polystyrene, polyethylene, polypropylene, polyvinyl chloride (PVC) or a material resistive to ultraviolet (UV) radiation. The support member 300 can be formed, for example, by injection molding.

The support member 300 includes a ridge 307 at a periphery of the support member 300. The ridge encircles a PV cell, such as thin film PV cell, when secured against the support member. When the PV cell is mounted against the support member 300 to form a PV module, the PV cell is housed in a valley defined by the ridge 307. A light receiving surface of the PV cell is below the ridge. The ridge 307 can be unitary (or single-piece) with the support member 300.

The ridge 307 can enable PV modules to be stacked, such as during shipping and/or storage. For example, when stacked, the ridge 307 of a first PV module having a first PV cell mates with a trough in an underside of a support member of an adjacent second PV module having a second PV cell. As such, the second PV module does not come in contact with a light receiving surface of the first PV cell, which can aid in preventing the second PV module from damaging the first PV cell. This can advantageously preclude the need for additional filler material to protect PV cells during storage and/or transport, thereby aiding in easing storage and/or transport of PV modules.

### Mounting Systems

Another aspect of the invention provides mounting systems for PV modules. Some embodiments provide mounting systems configured to be coupled to PV modules provided herein. In some cases, mounting systems comprise buss bars electrically coupled to a power distribution system, including an energy storage system, and for coming in electrical communication with PV modules with the aid of electrical connection members. Mounting systems can include mounting frames for mounting PV modules provided herein at a target location, including a location for sale, storage, installation or distribution, such as, for example, a plot of land, a rooftop, a vehicle or a warehouse.

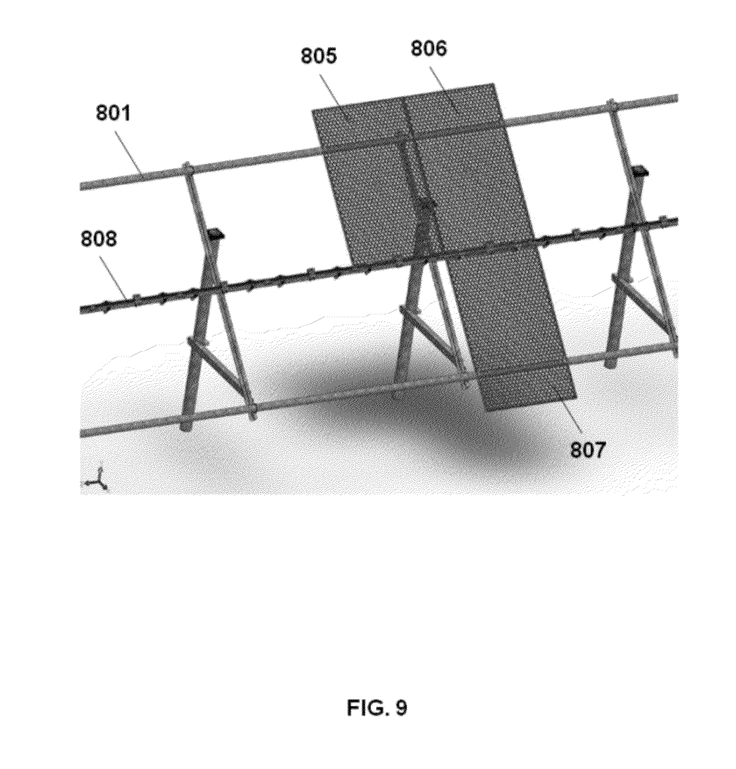

FIG. 8 shows a mounting frame 800, in accordance with an embodiment of the invention. The mounting frame 800 is configured to hold or support a plurality of PV modules. The mounting frame 800 includes two outer horizontal support members 801 and an inner horizontal support member 802, and support member 803 that are orthogonal to the support members 801 and 802. The inner horizontal support member 802 is configured to hold an electrical buss bar (also “buss bar” and “busbar” herein) for electrically coupling PV cells of PV modules to a power distribution system. The mounting frame 800 further includes vertical support members 804 for mounting the mounting frame to a surface, such as a rooftop or other location designated for installation (e.g., plot of land). The support members 801-803 are disposed on a first plane, and the support members 804 are disposed on a second plane that intersects the first plane. The angle between the first and second plane, θ, can be adjusted to maximize PV cell or PV module performance (e.g., power output).

The horizontal support members 801 and 802, as illustrated, have circular cross-sections. However, in other cases the support members 801 and 802 can have other cross-sections, such as oval, triangular, square, rectangular, pentagonal, hexagonal, heptagonal, octagonal, or octagonal.

In some embodiments, the support members 801-804 are formed of a metallic material, such as aluminum or steel, or carbon fiber, a polymeric material, or a composite material, such as fiberglass.

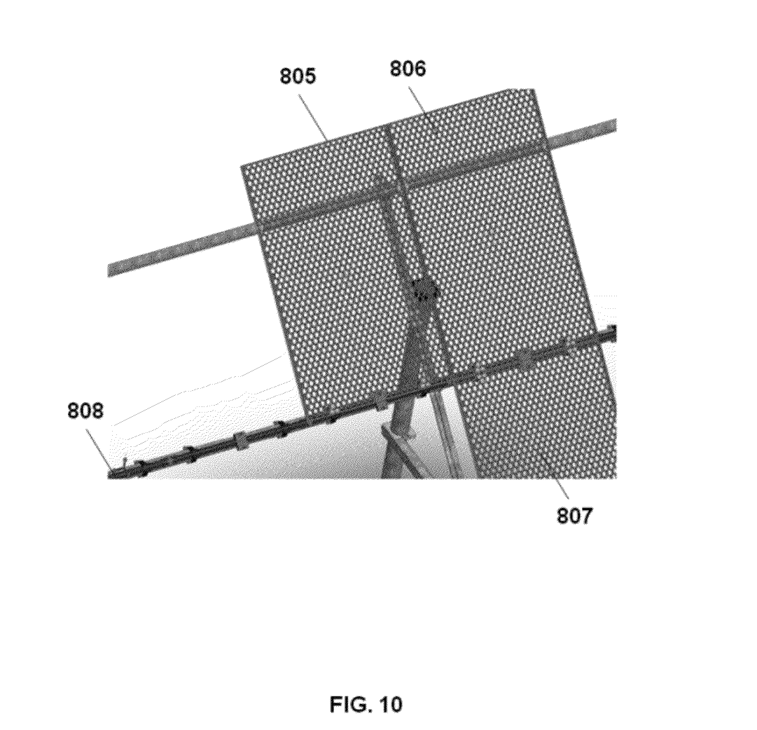

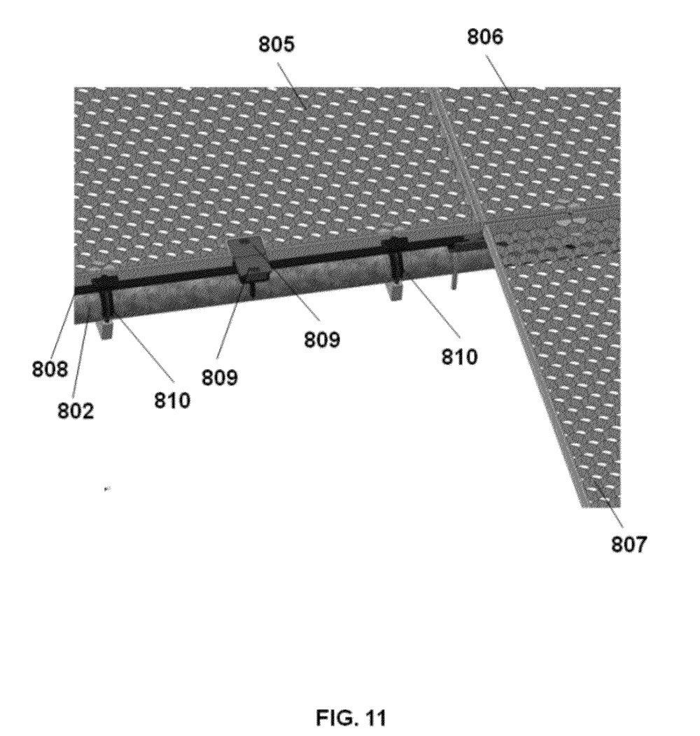

FIG. 9 shows a PV array having a first PV module 805, second PV module 806 and third PV module 807 mounted on the mounting frame 800 of FIG. 8, in accordance with an embodiment of the invention. The PV modules 805-807 comprise support members (see, e.g., FIG. 3) and PV cells (not shown). The PV modules 805-807 are electrically coupled to a buss bar 808 that is secured against (e.g., attached to) to the inner horizontal support member 802. FIG. 10 is an enlarged view of a portion of the mounting frame 800 and PV modules 805-807 of FIG. 9.

In some embodiments, the buss bar 808 enables a user to electrically couple a PV module to the buss bar 808 in a plug-and-play (or snap-in) fashion, which can aid in simplifying the installation of PV modules. In an example, a user mounts a PV module to the mounting frame 800 and electrically couples the PV module to the buss bar 808 in a time period of at most about 10 minutes, 5 minutes, 1 minute, 30 seconds, 10 seconds, or less.

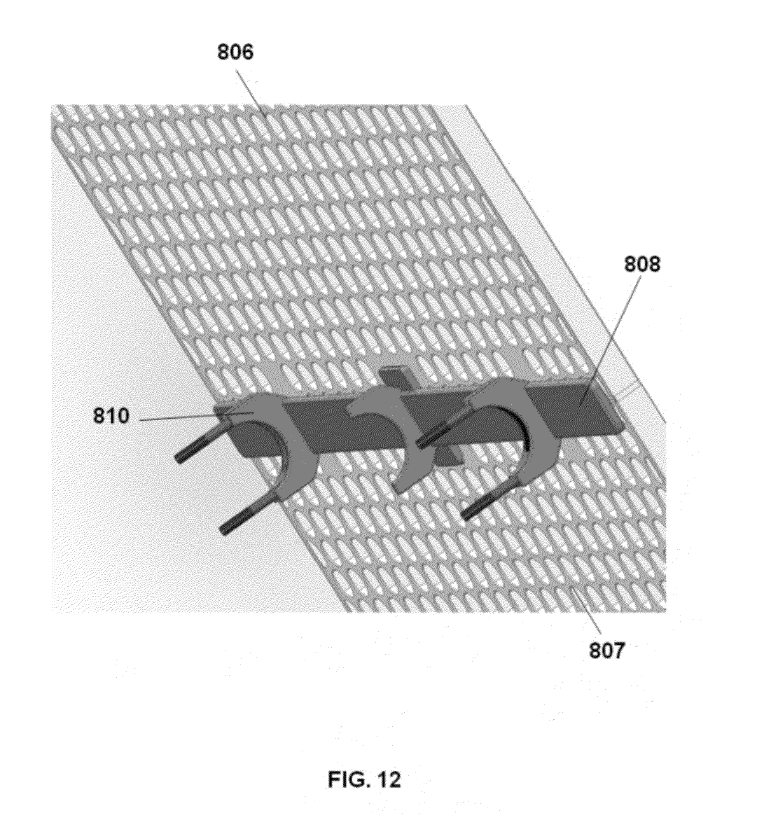

With reference to FIG. 11, the PV modules 805-807 are each in electrical communication with the buss bar 808 with the aid of an electrical attachment member 809. Illustrated are two electrical attachment members 809 for electrically coupling the buss bar 808 to the first PV module 805 and a fourth PV module (not present) below the first PV module 805 and adjacent to the third PV module 807. Attachment members 810 mount the first PV module 805 to the inner horizontal support member 802.

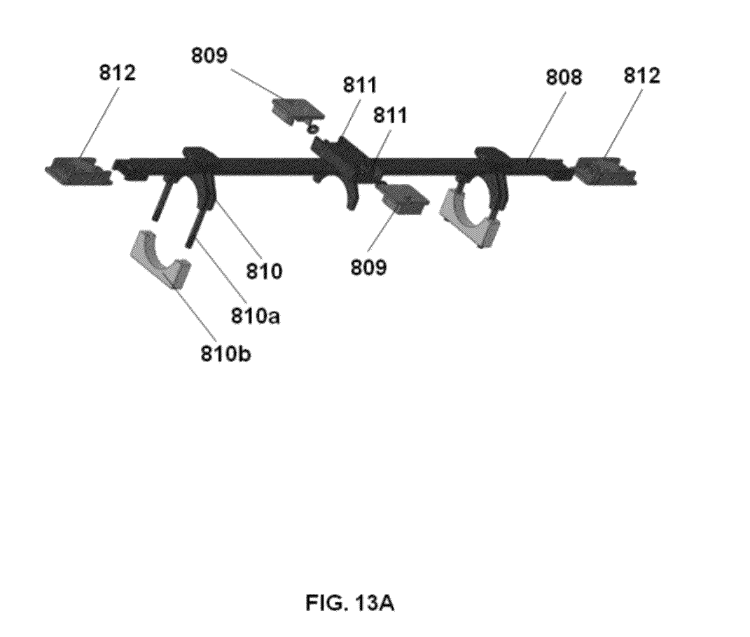

FIG. 12 is a schematic perspective view of an underside of the second PV module 806 and third PV module 807 showing buss bar 808 and attachment members 810. The attachment members 810 are configured to encircle the inner horizontal support member 802.

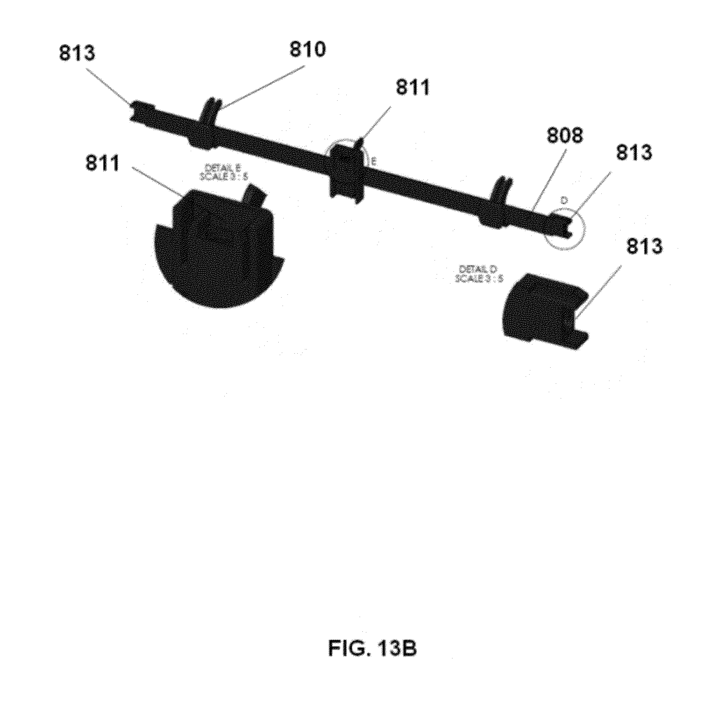

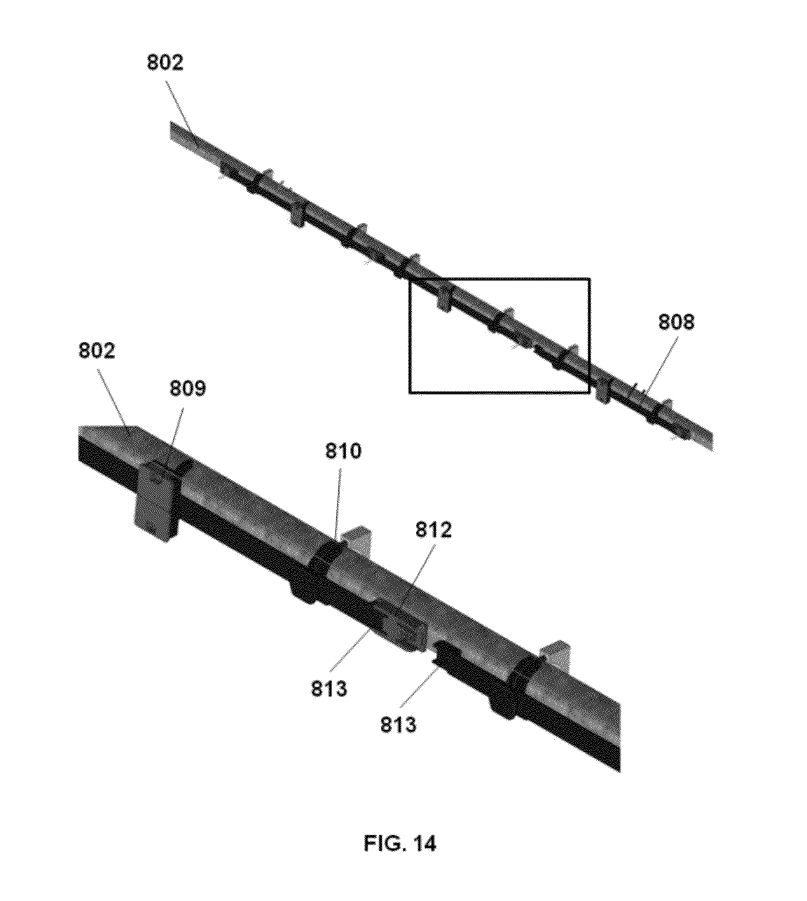

FIG. 13A schematically illustrates a mounting and electrical attachment system (collectively, “attachment system” herein) having the buss bar 808, electrical attachment members 809 and attachment members 810. The attachment members 810 include screw portions 810a and fasteners 810b for mating with the screw portions and securing the attachment members 810 against the inner horizontal support member 802. The attachment system is configured to physically and electrically couple PV modules to the mounting frame 800, including a power distribution system of the mounting frame 800. The electrical attachment members 809 are configured to electrically couple to PV modules (not shown). Each electrical attachment member 809 is configured to mate with an electrical receptacle (“receptacle”) 811 of the attachment system. The attachment system includes linkers 812 for electrically coupling adjoining buss bars. With reference to FIG. 13B, the receptacle 811 includes a female receptacle 811a for coupling with a male prong of an electrical attachment member 809 (see below). The buss bar 808 includes side female receptacles 813 for coupling to male prongs of the linkers 812, there by electrically coupling adjacent buss bars 808, as shown in FIG. 14, which shows a plurality of buss bars mounted on the inner horizontal support member 802. The bottom image of FIG. 14 is an enlarged view of the boxed portion of the top image. In the illustrated example, there is a break in the buss bar 808, as shown by the detached receptacle 813 and linker 812 (bottom image).

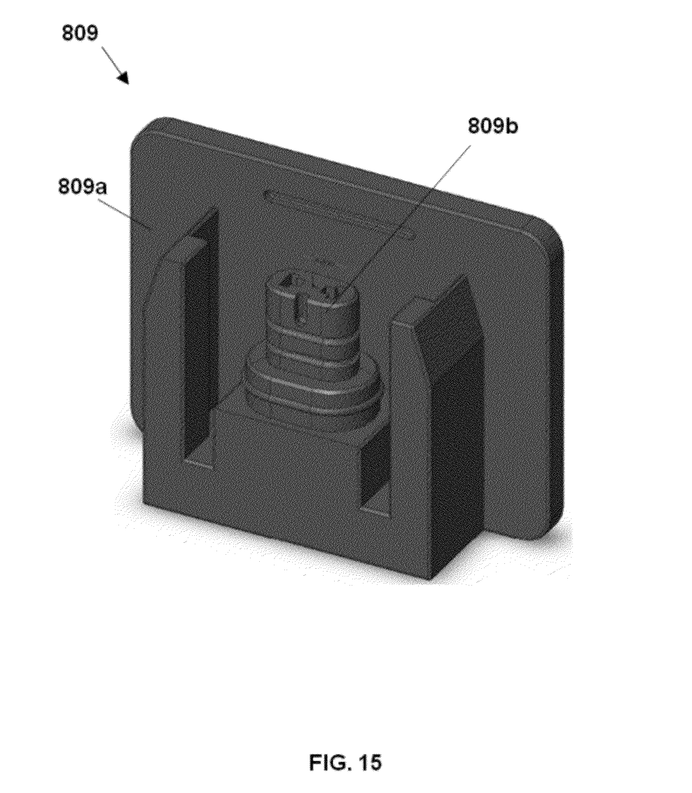

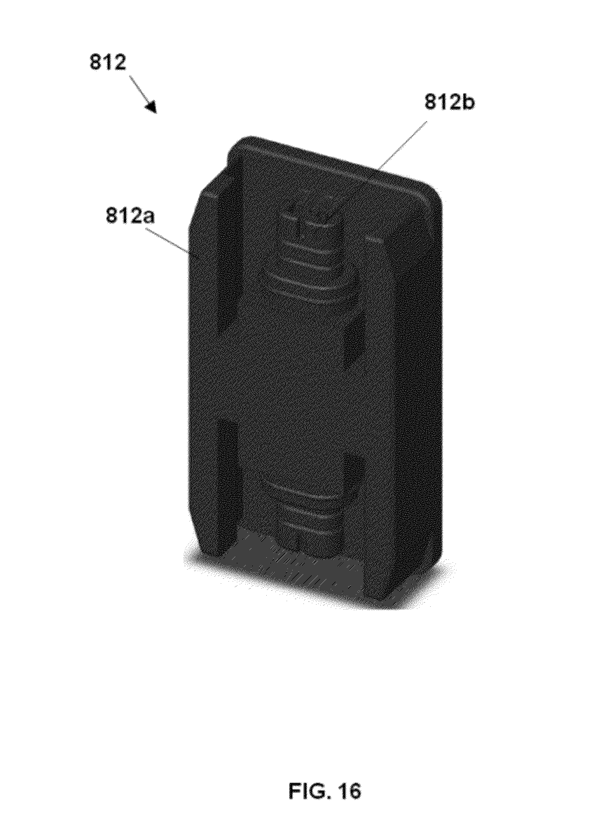

Electrical attachment members 809 and linkers 812 can have male or female configurations. They can be configured to couple to a receptacle of opposite (i.e., female or male) configuration. FIG. 15 shows an individual electrical attachment member 809 having a body portion 809a for insertion into a slot of a support member (e.g., slot 304 of the support member 300 of FIG. 3), in accordance with an embodiment of the invention. The electrical attachment member 809 includes a male prong configured to be coupled with a corresponding female receptacle 811 of the buss bar 808. FIG. 16 shows an individual linker 812 having a body portion 812a and a male prong configured to be coupled with a female receptacle of the buss bar 808, in accordance with an embodiment of the invention.

In some situations, the individual electrical attachment member 809 is integrated with a support member for supporting one or more PV cells, such as, for example, the support member 300 of FIG. 3. In some cases, the individual electrical attachment member 809 is unitary (or single-piece) with the support member (see, e.g., FIG. 3). In an example, the individual electrical attachment member 809 is formed from the same material as the support member and is formed to be unitary with the support member.

In some situations, at least one of the linkers 812 of FIG. 13A is integrated with the buss bar 808. In some cases, the linker 812 is unitary (or single-piece) with the buss bar 808. The linker 812 can mate with a receptacle on an adjacent buss bar. In such a case, the buss bar 808 can include only a single receptacle 813 to mate with a linker 812 of the adjacent buss bar.

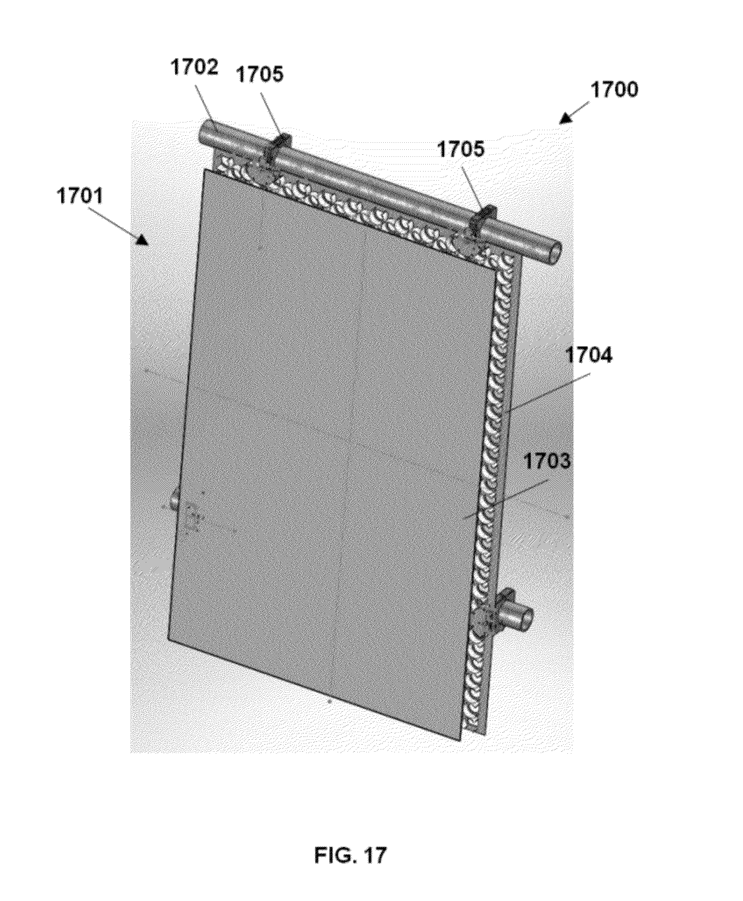

There are alternative approaches for attaching PV modules to mounting frames. FIG. 17 shows a PV array 1700 having a PV module 1701 mounted on a mounting frame having a side support member 1702. The side support member 1702 has a circular cross-section. The PV module 1701 includes PV cells 1703 adjacent to a support member 1704. The PV cells 1703 is shown removed from the support member 1704, but when installed can be in contact with the support member 1704, in some cases with one or more intervening layers. The PV module 1701 is secured to a side support member 1702 with the aid of attachment members 1705. The side support member 1702 in some cases is an outer horizontal support member 801 or an inner horizontal support member 802 described in the context of FIG. 8.

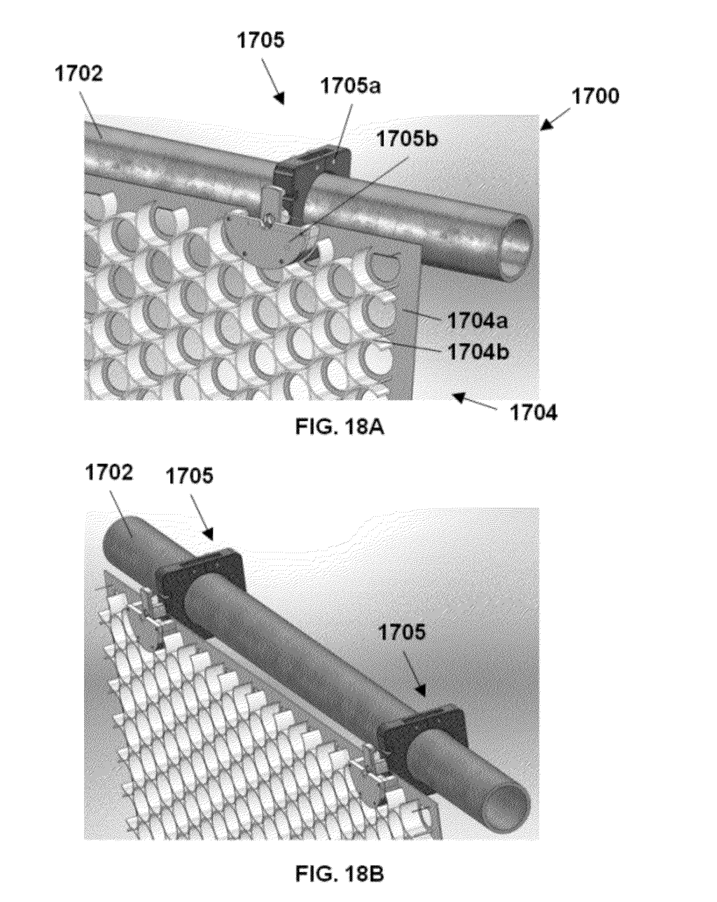

With reference to FIGS. 18A and 18B, the support member 1704 includes a panel 1704a and a support structure 1704b having circular holes, in accordance with an embodiment of the invention. The panel 1704a comprises a plurality of holes. An individual hole of the plurality of holes is aligned with the circular holes of the support structure 1704b. An individual hole of the panel 1704a has a diameter (D) that is smaller than a width (or diameter) (W) of a circular hole of the support structure 1704b. With reference to FIGS. 18A and 18C, an individual attachment member 1705 includes a clamping member 1705a that is configured to encircle the side support member 1702, and a securing member 1705b for securing the attachment member 1705 to the support member 1704. The attachment member 1705 of FIG. 18C is an “open” configuration, which can permit the location of the attachment member 1705 to be adjusted along the side support member 1702. When the attachment member 1705 is secured to the support member 1704, the clamping member 1705a rests against a first surface of the panel 1704a and the securing member 1705b rests against a second surface of the panel 1704a, the second surface opposite from the first surface.

In some situations, the securing member 1705b is integrated with the support member 1704. In some cases, the securing member 1705b is unitary (or single-piece) with the support member 1704. In an example, the securing member 1705b is formed from the same material as the support member 1704 and is formed to be unitary with the support member 1704.

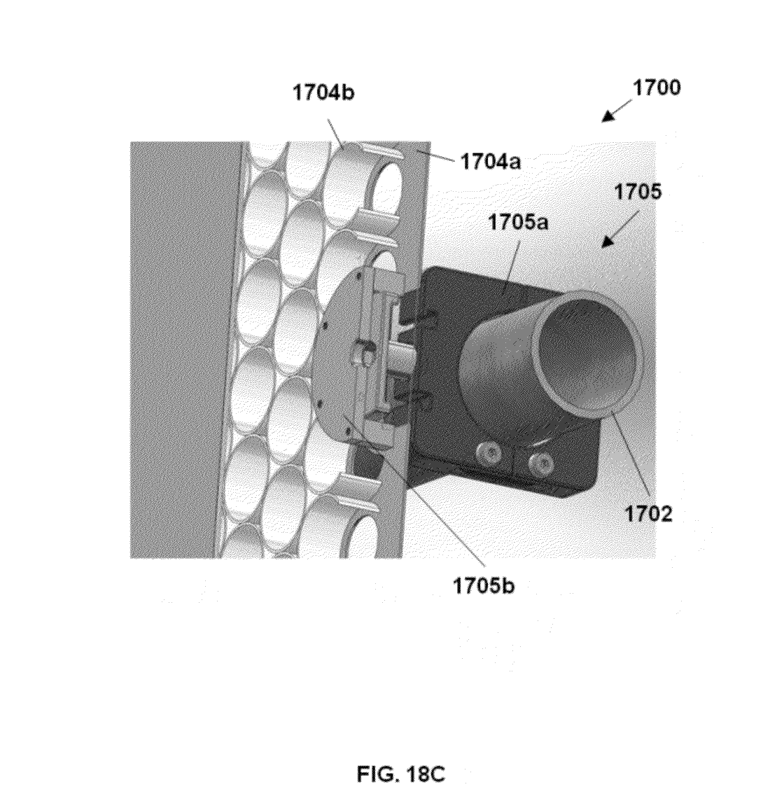

FIGS. 19A-19D show the attachment member 1705 in further detail, in accordance with an embodiment of the invention. The attachment member 1705 is in a clamped (or “closed”) configuration, which can permit the location of the attachment member 1705 along the side support member 1702 to be adjusted, as desired. The attachment member 1705 includes a rotatable locking member 1705c that is configured to be inserted into a receptacle 1705d and rotate within the receptacle to the clamped configuration. The locking member 1705c can be inserted into the receptacle 1705d through a opening 1705e (see FIG. 19D). The attachment member 1705 has a hole 1705f for encircling the side support member 1702 or other similar support structure.

During use, a user inserts the side support member 1702 into the hole 1705f of the attachment member 1705 and slides the attachment member 1705 to a desired location along the side support member 1702. The user then secures the attachment member 1705 to the support member 1704 of the PV module 1701 by inserting the attachment member on a slot disposed along the periphery of the support member 1702 and rotating the locking member 1705c along the receptacle 1705d to the locking position, as shown in FIGS. 19A-19D.

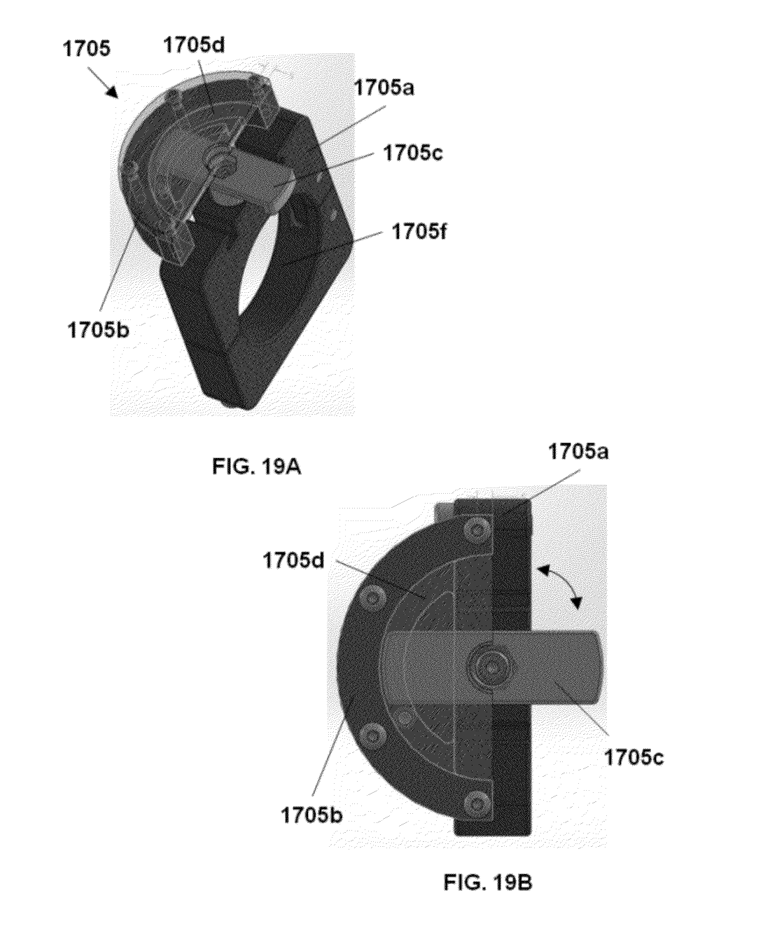

FIG. 20 shows a mounting frame for a PV module (“module”), in accordance with an embodiment of the invention. The frame of FIG. 20 can accommodate one module, though the frame can be sized to accommodate several modules, such as at least 2, 3, 4, 5, 6, 7, 8, 9, 10, 20, 30, 40, 50, 100, or more modules. A PV module 11 is shown mounted on the mounting frame. The module 11 can be as described in FIGS. 1 and 2. The module 11 can fit without binding into a bottom channel 12 which has a “C” cross sectional shape. The channel can contain one or more holes (not shown) for water drainage. The PV module rests against closed top channel 13 and is secured with the aid of clips 14. While the channel 13 is depicted with a square opening, it can also function with a circular, oval, triangular, rectangular or other geometrically-shaped opening, such as a circular opening as can be attained with a pipe or tube structure. The design of clips 14 can be modified to accommodate the round channel. Male plugs 15 snap into the female receptacle described in FIG. 2 when the module is mounted. Alternatively, the plugs 15 can be female plugs that couple with a male receptacle of the PV module of FIG. 2. Interconnect module wiring, diodes, and even small inverters can be accommodated in the opening of channel 13.

In some embodiments, the top closed channel acts as a buss bar container that allows module interconnection and other electrical functions along a string of modules. Not shown explicitly in the drawing is a sealable electrical access port 16 located opposite plugs 15 and between clips 14. Once the electrical connections between the modules on a frame are made, the port 16 is sealed. This can be done in the factory where an entire string of modules is assembled, but it can be accomplished in the field.

While the mounting frame of FIG. 20 has been described in the context of PV modules provided herein, the mounting frame can be used with other modules, such as conventional PV modules. The skilled artisan will understand that current PV modules may need to be adapted with plug receptacles to electrically couple current PV modules to the mounting frame, including the buss bar (see below). A conventional PV module can be constructed with plug connections that can make it suitable for the herein described mounting system, since the mounting system is not physically dependent on the PV modules provided herein, but the PV modules described herein can help in reducing the net system cost.

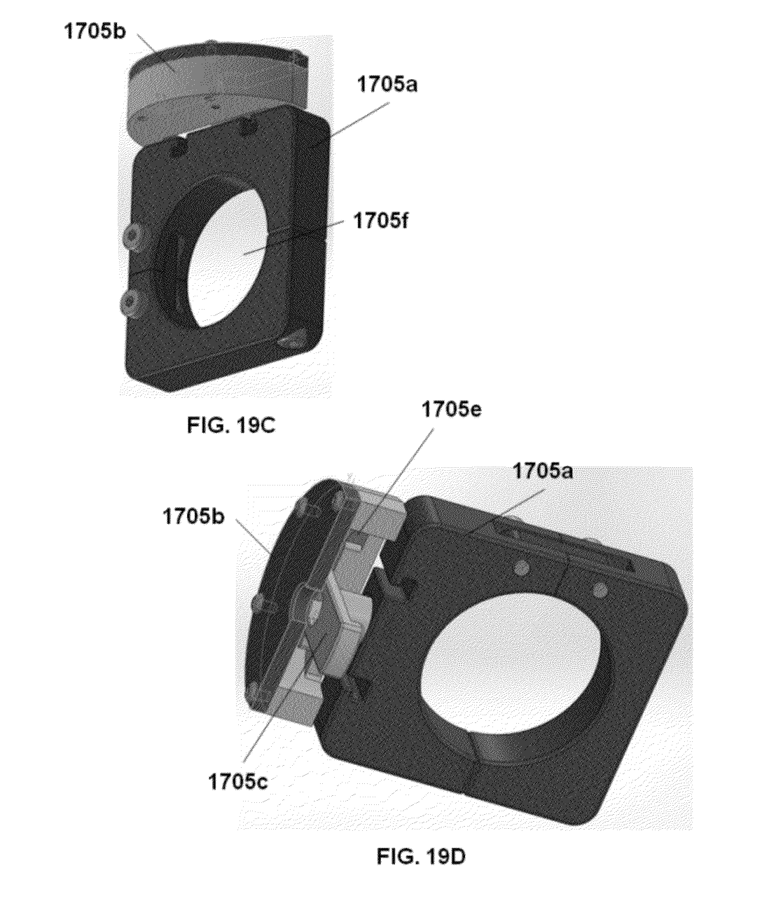

A schematic cross-sectional side view of the mounting system for a single row of modules is illustrated in FIG. 21, in accordance with an embodiment of the invention. Vertical supports 17 can extend an appropriate distance into the ground to provide adequate stability, such as, e.g., to a depth of at least about 1 inches, 2 inches, 3 inches, 4 inches, 5 inches, 6 inches, 12 inches, 24 inches, 48 inches, or more. Angle θ can be selected to aid in optimizing the average solar flux on PV module 11 received during the year. Angle θ can be adjusted with the aid of a rotation mechanism (not shown) to adjust the orientation of the PV module 11, as may be required, such as to optimize the average solar flux in a time of year. Support 18 is placed at the module intersections, and provides support to the modules along its edges. Support 18 can be provided at each module intersection while supports 17 can be provided at a larger spacing (or interval), depending on the strength of the channels and structural loading, such as loading on an array having a plurality of PV modules. Full edge support of the module can reduce high stress points from the mounting, but may require additional support material.

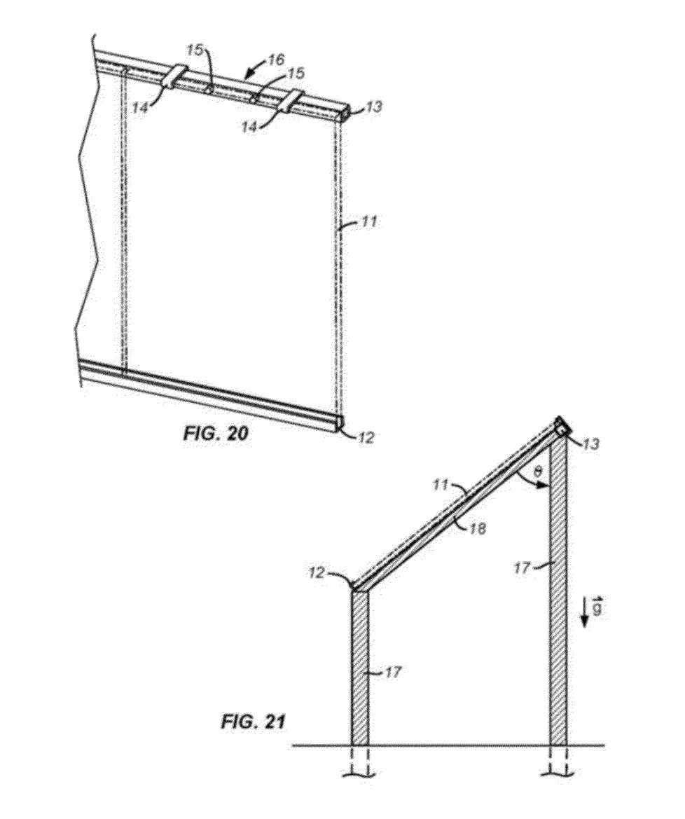

FIG. 22 is a schematic expanded view of the region of closed top channel 13 (the buss bar) containing electrical connecting plugs or features for coupling a PV cell to a power transmission line. The numerical identifications of the elements are the same as those specified in previous figures. The closed channel 13 can include electrical elements 19 other than wiring, such as diodes and mini or micro inverters enabling each individual PV module can output AC power directly, which simplifies wiring and minimizes module shading problems. Also, a single small inverter can service a number of modules, for instance an array of 4 or 6 modules which are factory pre-mounted in the support channels. In some cases, the closed channel 13 can include sensors or wiring for sensors. Sensors can enable an operator to perform diagnostics on the PV module mounting on the mounting frame.

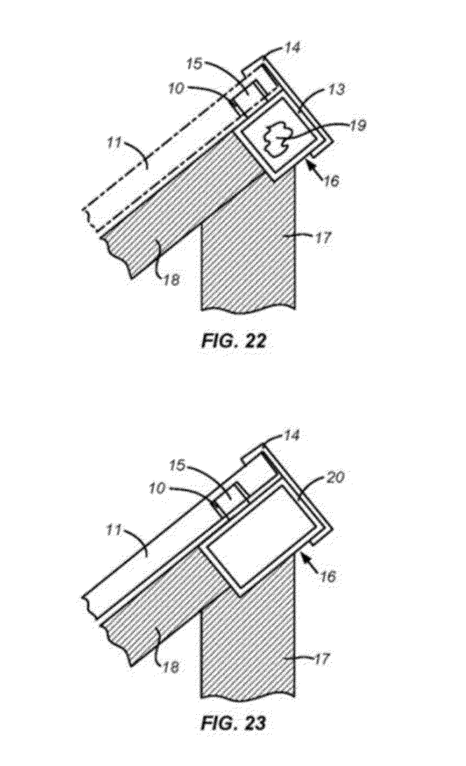

FIG. 23 shows that closed channel 13 can be larger (represented by channel 20) if additional space is required for electronics packaging. The channel can have various cross-sections, such as a circular, oval, triangular, square, rectangular, pentagonal or hexagonal cross-section. In an example, the closed channel 20 is circular or elliptical. Alternatively, the channel 20 can be an open channel and provided with a cover along at least a portion of the channel to provide an enclosure.

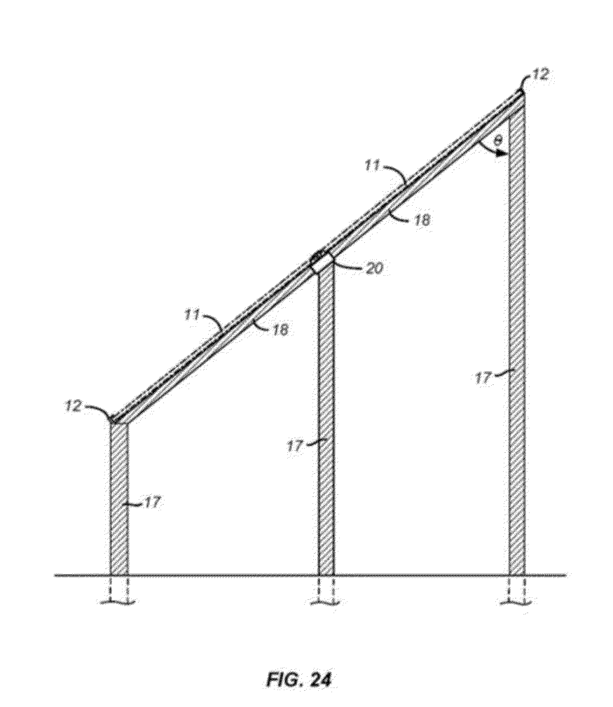

PV modules can be mounted on mounting frames in a side-by-side configuration, though in some cases mounting frames can permit PV modules to mounted in other configurations. FIG. 24 is a schematic cross-sectional side view showing the mounting of a double row of PV modules 11. The mounting frame of FIG. 24 is similar to that show in FIG. 21, except that the mounting frame includes a first PV module 11a and a second PV module 11b inverted with respect to the first module. The first PV module 11a and second PV module 11b are configured to electrically couple to the buss bar of the mounting frame at the central channel 20 of the mounting frame.

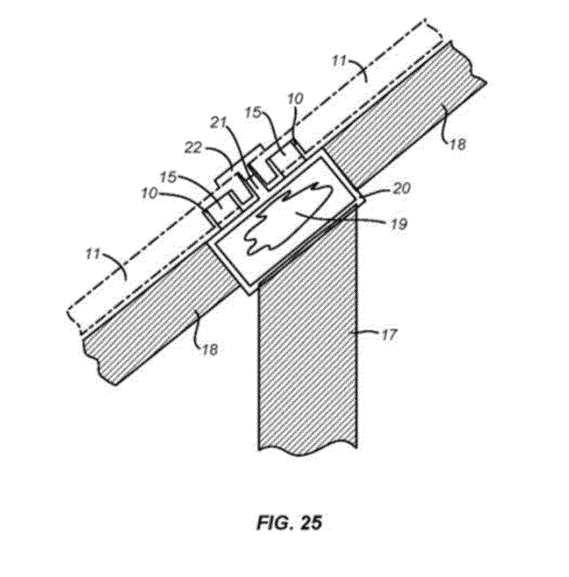

FIG. 25 is an expanded view of the connector region of FIG. 24 showing plugs 15 from each of the PV modules mounted on channel 20. The larger channel volume allows room for electronics for the two or more PV modules. In this configuration, clips 14 used on the single module mount are replaced by “T” clips consisting of elements 21 and 22. These clips need not extend the entire width of the module. Elements 21 may be secured (e.g., bolted) to channel 20 or they can be secured (e.g., welded) at select points along the channel 20. The “T” clips can be formed either in the factory or in the field. While this mounting system has been described in detail for the portrait mode of module orientation, the mounting system can be adapted to a 90 degree orientation for mounting the PV modules in landscape mode. In some cases, PV modules can be coated with a layer of protective material (e.g., painted) to protect against exposure to various environmental factors, such as ultraviolet (UV) light. The layer of the protective material can include, for example, epoxy or a titanium oxide (TiOx).

PV modules and mounting systems provided herein can facilitate installation of PV modules at a predetermined location. Such installation includes mounting the PV module on a mounting system, such as a mounting frame, and electrically coupling the PV module to a power distribution system. In some cases, a PV module can be installed in a time period of at most about 2 hours, or 1 hour, or 30 minutes, or 20 minutes, or 10 minutes, or 5 minutes, or 1 minute, or less.

### Rooftop Mounting

Another aspect of the invention provides mounting systems for mounting PV modules to rooftops. Rooftop mounting systems provided herein can be used with PV modules provided herein, such as the PV modules described in the context of FIGS. 1 and 2.

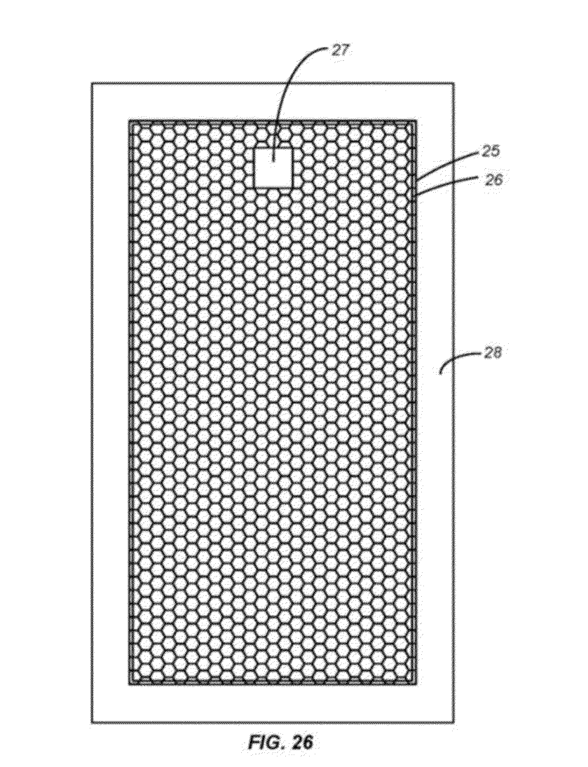

In some embodiments, a PV module includes a support member having a molded honeycomb configuration, as described, for example, in the context of FIGS. 1 and 2. Variants of the honeycomb configuration can be obtained, such as by using a mold of desired shapes and/or features during injection molding. One possible variation that can be appropriate for residential rooftop mounting is shown in FIG. 26. FIG. 26 is a schematic top view of a PV module 25 having a honeycomb support member, in accordance with an embodiment of the invention. The PV module of FIG. 26 can include a support member having a support structure, top sheet and back sheet, as described above in the context of FIG. 1. The support structure can have a honeycomb configuration.

In an example, the PV module 25 of FIG. 26 has outside dimensions of about 4 feet by 8 feet, which can correspond to the dimensions of a sheet of roofing sheathing (i.e., plywood) that is approximately half an inch thick. The PV module can be adapted for use in rooftop applications. In some cases, the PV module 25 can include a central depressed region indicated by perimeter line 26 into which will fit a thin glass solar module, a molded-in opening 27 for a J-box connection, and a thin flashing region 28 all around the structure, which can be an extension of top sheet 8a of FIG. 1. The PV module 25 can be modified to accommodate rafters for rooftop installation. An outer surface of the PV module 25 has no openings where rain can enter, except for the J-box opening whose actual position can be changed if necessary to avoid interference with roof rafters.

With continued reference to FIG. 26, the solar module sits in a recess whose edge is defined by line 26 and is sealed to the honeycomb top sheet all around its edge with a waterproof elastomeric material. In addition, a similar seal can be placed around the J-box opening as a secondary (backup) seal. If necessary the module can be “spot” attached at other selected positions on the top sheet. The basic idea is to provide a robust but flexible attachment that can accommodate thermal expansion stresses that the module may encounter over its lifetime, and to also provide a reliable water seal.

PV modules and mounting systems provided herein enable PV modules to be readily removed and/or serviced without having to remove an entire PV array. This can enable the PV array to function during the removal and replacement of a PV module of the array.

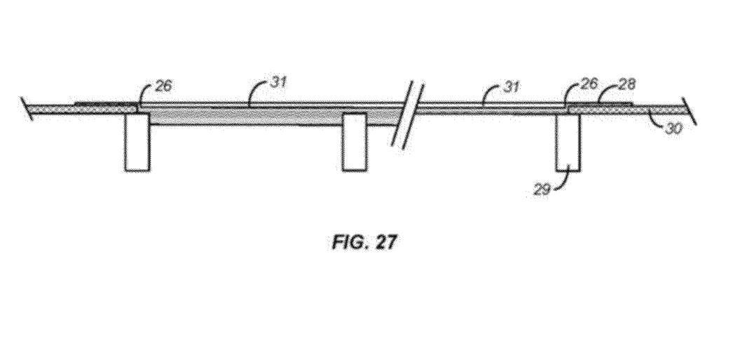

FIG. 27 schematically illustrates a PV module and honeycomb support member, in accordance with an embodiment of the invention. The view is a cross-section through roof rafters 29, roof sheathing 30, and honeycomb PV module, which can be used in place of a sheet of sheathing. The shaded area is the honeycomb panel (as shown in FIG. 1) with its thin solid side 8a (see FIG. 1) adjacent to the thin glass PV module 31 and the side with holes for ventilation 8b toward the attic space. The honeycomb panel can be approximately as thin as the sheathing, shown on the right of the figure, or thicker with molded-in rafter recesses, as shown on the left of the figure. In either case, if extra strength is required, some cross bracing between the rafters (not shown) may be added with little to no loss of functionality. Flashing area 28 extends over the roof sheathing. The honeycomb panel is held to the rafters with a panel adhesive, such as, for example, “Liquid Nails” or a similar adhesive.

In some cases, the honeycomb panel can be secured to the rafters with mechanical fasteners, such as screws or nails in flashing area 28. Opening 27 through which the J-box on the module fits is not explicitly indicated in the figure, but can be placed in a region that does not interfere with a rafter. Wiring, which can include small inverters, can be disposed in the attic or other structural feature. The J-box location shown in FIG. 26 can be used with PV modules that are mounted in landscape mode with either standard 16-inch or 24-inch rafter spacing. For portrait mode, the indicated J-box position will accommodate rafters on 16-inch spacing, but it can be moved (for example nearer either corner) to accommodate rafters on 24-inch spacing. Attic ventilation, either forced or natural draft, can help remove heat from the backs of the honeycomb PV modules, thus helping keep the PV module cool and increasing its electrical output especially during the hotter summer months. This may be preferable in instances in which PV cell performance is inversely proportional to PV cell temperature.

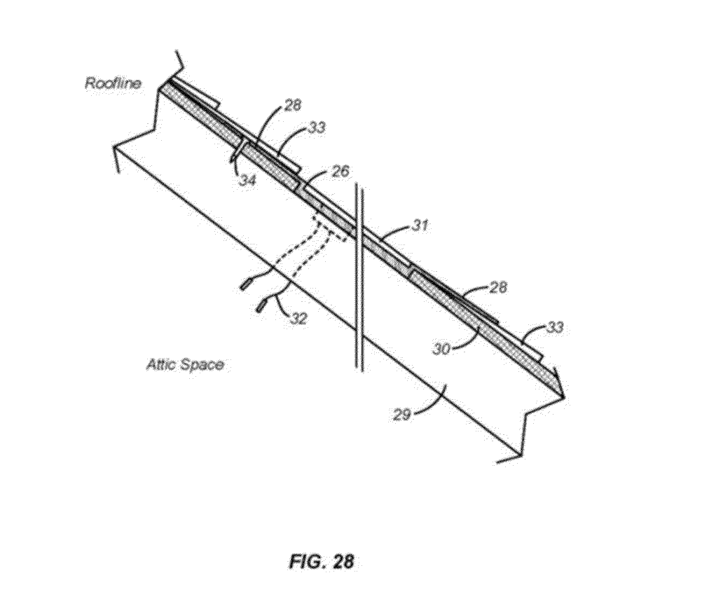

FIG. 28 shows a PV module mounted on a roof structure, in accordance with an embodiment of the invention. The foreshortened view is along a roof rafter 29 with the higher side being near the roofline to provide adequate attic space for purposes of installation. The J-box with its connecting wires 32 also should be positioned near the higher side of the solar module. Conventional composite roofing shingles 33 are shown extending over flashing area 28 on the higher side of the module panel, and going under area 28 on the lower side. Along both edges of the module (not shown) the shingles cover and are sealed to the flashing area. This sealing system is similar to that used extensively for sky light structures. On the higher side of the panel where the shingles cover the flashing, nails or screws 34 may be used as an addition to, or in place of, the adhesive to secure the panel to the rafters.

There are a large number of benefits that derive from the honeycomb PV module roof mounting system just described. They include but are not limited to: 1) A lightweight stiff solar module that is factory assembled as a drop in replacement for a sheet of roof sheathing; 2) a solar module that needs no additional roof mounting structure and roof penetrating attachment hardware; 3) ready replacement of a module with no disruption of the existing roof structure; 4) ready wiring connections made inside the attic of the house and protected from the weather; 5) pleasing esthetics with a system that conforms to normal roof geometry; 6) reduced balance of system costs resulting from larger module area per J-box, economical injection molded parts, reduced installation labor, and cheaper wiring.

It should be understood from the foregoing that, while particular implementations have been illustrated and described, various modifications can be made thereto and are contemplated herein. It is also not intended that the invention be limited by the specific examples provided within the specification. While the invention has been described with reference to the aforementioned specification, the descriptions and illustrations of the preferable embodiments herein are not meant to be construed in a limiting sense. Furthermore, it shall be understood that all aspects of the invention are not limited to the specific depictions, configurations or relative proportions set forth herein which depend upon a variety of conditions and variables. Various modifications in form and detail of the embodiments of the invention will be apparent to a person skilled in the art. It is therefore contemplated that the invention shall also cover any such modifications, variations and equivalents. It is intended that the following claims define the scope of the invention and that methods and structures within the scope of these claims and their equivalents be covered thereby.

1. A photovoltaic (PV) module, comprising:
a) a layer of an optically transparent material;
b) a photovoltaic cell adjacent to said layer of the optically transparent material, said photovoltaic cell configured to generate electricity upon exposure to light;
c) a dielectric layer adjacent to said photovoltaic cell;
d) a metal foil adjacent to the dielectric layer, said metal foil for providing a moisture barrier;
e) a support member adjacent to said metal foil;
f) an edge seal between said layer of the optically transparent material and said metal foil; and
g) an electrical connection member in electric communication with said photovoltaic cell, said electrical connection member for electrically coupling said photovoltaic cell to an electric buss bar.

2. The PV module of claim 1, wherein said support member comprises through holes in a honeycomb configuration.

3. (canceled)

4. The PV module of claim 1, wherein said photovoltaic cell is a thin film photovoltaic cell.

5. (canceled)

6. The PV module of claim 1, wherein said dielectric layer includes polyethylene terephthalate.

7. The PV module of claim 1, wherein said metal foil includes aluminum.

8. The PV module of claim 1, wherein said support member is formed of a polymeric material.

9.-10. (canceled)

11. The PV module of claim 1, wherein said support member includes a thin back sheet with convective heat ventilation holes.

12.-14. (canceled)

15. The PV module of claim 1, wherein said layer of the optically transparent material is formed of tempered glass.

16. (canceled)

17. The PV module of claim 1, wherein said layer of the optically transparent material is formed of a transparent flexible moisture barrier sheet.

18. A photovoltaic module, comprising:
a photovoltaic (PV) cell having an active material for generating electricity upon exposure of the PV cell to light; and
a support member adjacent to said PV cell, said support member for providing structural support to said PV cell, said support member having a plurality of holes extending through said support member, an individual hole of said plurality of holes defined by a wall having at least one side.

19. The PV module of claim 18, wherein said support member is formed of a polymeric material.

20. The PV module of claim 18, wherein said plurality of holes are in a honeycomb configuration.

21. (canceled)

22. The PV module of claim 18, wherein said support member comprises a support structure having said plurality of holes and a sheet adjacent to said support structure and disposed away from said PV cell, wherein each of said plurality of holes of said support structure has a width (W).

23. The PV module of claim 22, wherein said sheet has holes aligned with said plurality of holes of said support structure, an individual hole of said plurality of holes of said sheet having a diameter (D), wherein D is less than W.

24. The PV module of claim 18, wherein said wall has at least three sides.

25.-27. (canceled)

28. The PV module of claim 18, wherein said support member includes a ridge encircling said PV cell, a light receiving surface of said PV cell below said ridge.

29.-52. (canceled)

53. A photovoltaic array, comprising:
a mounting frame;
a buss bar secured against said mounting frame, said buss bar for providing power distribution; and
a plurality of photovoltaic (PV) modules secured against said mounting frame and electrically coupled to said buss bar, an individual PV module of said plurality of PV modules having a support member for providing structural support to a PV cell of said individual PV module, said support member having a plurality of holes extending through said support member.

54. The PV array of claim 53, wherein said mounting frame comprises a first and second support member and a third support member disposed between said first and second support members, wherein said buss bar is secured against said third support member.

55. The PV array of claim 54, wherein said first, second and third support members have circular cross-sections.

56. (canceled)

57. The PV array of claim 53, wherein said plurality of PV modules are each electrically coupled to said buss bar with the aid of an electrical attachment member coupled to an electrical receptacle of said buss bar.

58.-68. (canceled)
